(19) United States
(12) Patent Application Publication
(10) Pub. No.: US 2024/0282805 A1
(43) Pub. Date: Aug. 22, 2024

(54) SEMICONDUCTOR DEVICE AND SEMICONDUCTOR MODULE

(71) Applicant: ROHM CO., LTD., Kyoto (JP)

(72) Inventor: Bungo TANAKA, Kyoto (JP)

(73) Assignee: ROHM CO., LTD., Kyoto (JP)

(21) Appl. No.: 18/435,699

(22) Filed: Feb. 7, 2024

(30) Foreign Application Priority Data
Feb. 17, 2023 (JP) 2023-023609

(51) Int. Cl. H01L 23/522

(52) U.S. Cl. CPC H01L 28/20; H01L 23/5228

(57) ABSTRACT

The present disclosure provides a semiconductor device. The semiconductor device includes: a substrate; an element insulating layer, disposed on the substrate; and a semiconductor resistive layer, disposed within the element insulating layer. The semiconductor resistive layer extends along a first direction perpendicular to a thickness direction of the substrate and includes an uneven portion along the thickness direction.

### TECHNICAL FIELD

The present disclosure relates to a semiconductor device and a semiconductor module.

### BACKGROUND

As an example of a semiconductor device, a structure including a semiconductor substrate, an insulating layer formed on the semiconductor substrate, and a semiconductor resistive layer formed on the insulating layer is known (for example, with reference to Patent Document 1).

### BACKGROUND TECHNICAL DOCUMENTS

### Patent Documents

[Patent Document 1] Japanese Patent Application Publication No. 2017-212299

### BRIEF DESCRIPTION OF THE DRAWINGS

FIG. 1 is a schematic top view of the semiconductor module according to the first embodiment.

FIG. 2 is a schematic top view of the first chip and the second chip in the semiconductor module of FIG. 1.

FIG. 3 is a schematic top view of the semiconductor resistive layer in the first chip.

FIG. 4 is an enlarged view of frame A1 in FIG. 3.

FIG. 5 is a schematic cross-sectional view of the first chip taken along line F5-F5 in FIG. 4.

FIG. 6 is a schematic cross-sectional view of the first chip taken along line F6-F6 in FIG. 3.

FIG. 7 is a schematic cross-sectional view of the first chip taken along line F7-F7 in FIG. 4.

FIG. 8 is an enlarged view of the first resistive end portion of the plurality of semiconductor resistive layers and its surroundings in FIG. 6.

FIG. 9 is a schematic perspective view of a plurality of semiconductor resistive layers.

FIG. 10 is an enlarged view of frame A2 in FIG. 8.

FIG. 11 is a schematic cross-sectional view showing an example of the manufacturing process of the first chip according to the first embodiment.

FIG. 12 is a schematic cross-sectional view showing the wiring layer and its surroundings in the process subsequent to FIG. 11.

FIG. 13 is a schematic cross-sectional view showing the wiring layer different from that shown in FIG. 12 and its surroundings in the process subsequent to FIG. 11.

FIG. 14 is a schematic cross-sectional view showing the manufacturing process subsequent to FIG. 12.

FIG. 15 is a schematic cross-sectional view showing the manufacturing process subsequent to FIG. 13.

FIG. 16 is a schematic cross-sectional view showing the manufacturing process subsequent to FIG. 15.

FIG. 17 is a schematic cross-sectional view showing the manufacturing process subsequent to FIG. 16.

FIG. 18 is a schematic cross-sectional view showing the manufacturing process subsequent to FIG. 14.

FIG. 19 is a schematic cross-sectional view showing the manufacturing process subsequent to FIG. 17.

FIG. 20 is a schematic cross-sectional view showing the manufacturing process subsequent to FIG. 19.

FIG. 21 is an enlarged schematic top view of the first resistive end portions of the plurality of semiconductor resistive layers and their surroundings on the first chip according to the second embodiment.

FIG. 22 is a schematic cross-sectional view of the first chip taken along line F22-F22 in FIG. 21.

FIG. 23 is a schematic cross-sectional view of the first chip taken along line F23-F23 in FIG. 21.

FIG. 24 is an enlarged schematic cross-sectional view of a portion of the semiconductor resistive layer and its surroundings regarding the first chip of the modified example.

FIG. 25 is an enlarged schematic cross-sectional view of a portion of the semiconductor resistive layer and its surroundings regarding the first chip of the modified example.

FIG. 26 is an enlarged schematic cross-sectional view of a portion of the semiconductor resistive layer and its surroundings regarding the first chip of the modified example.

FIG. 27 is an enlarged schematic cross-sectional view of a portion of the semiconductor resistive layer and its surroundings on the first chip of the modified example.

FIG. 28 is an enlarged schematic cross-sectional view of a portion of the semiconductor resistive layer and its surroundings regarding the first chip of the modified example.

### DETAILED DESCRIPTION OF THE EMBODIMENTS

Hereinafter, several embodiments of the semiconductor device and semiconductor module in the present disclosure will be described with reference to the accompanying drawings. In addition, in order to make the description simple and clear, the components shown in the drawings are not necessarily drawn at a fixed reduced scale. Further, in order to facilitate understanding, hatching may be omitted in cross-sectional views. The accompanying drawings merely illustrate embodiments of the present disclosure and should not be construed as limiting the present disclosure.

The following detailed description includes devices, systems and methods that embody the exemplary embodiments of the present disclosure. The detailed description is intended to be illustrative only, and is not intended to limit the embodiments of the present disclosure or the application and use of such embodiments.

### First Embodiment

### [Configuration of Semiconductor Module]

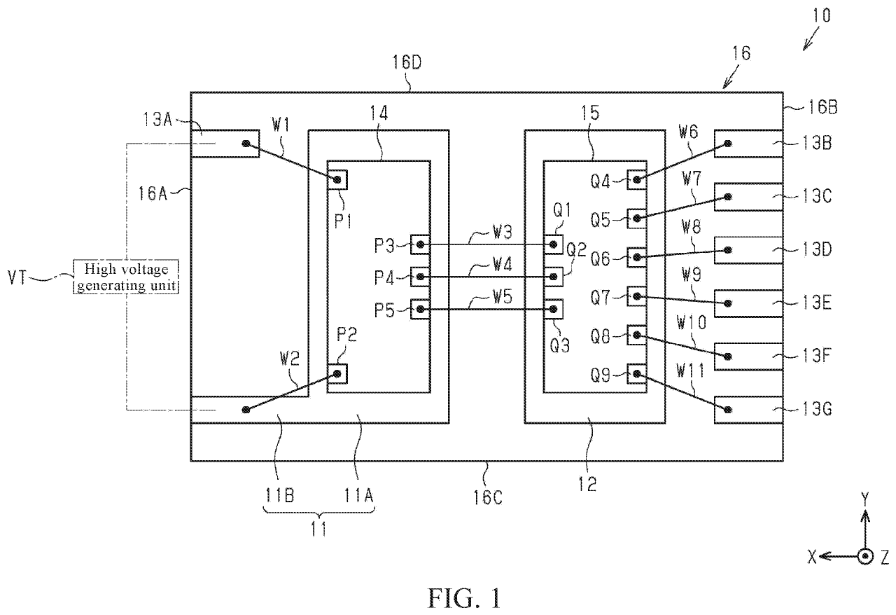

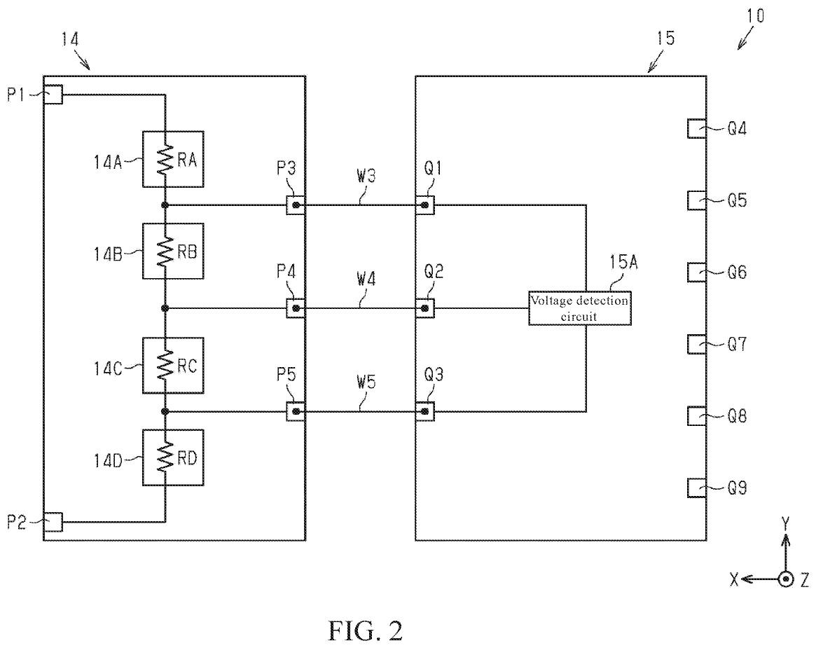

The structure of the semiconductor module 10 according to the first embodiment will be described with reference to FIGS. 1 and 2. FIG. 1 schematically shows the overall arrangement structure of the semiconductor module 10. FIG. 2 schematically shows the electrical structure and electrical connection structure of each of the first chip 14 and the second chip 15 described below in the semiconductor module 10. In addition, in FIG. 1, in order to facilitate understanding of the accompanying drawings, the internal components of the sealing resin 16 described below are shown by solid lines. In FIG. 2, in order to facilitate understanding of the accompanying drawing, the internal components of the first chip 14 and the second chip 15 are represented by solid lines.

In addition, the term “top view” used in the present disclosure means viewing the semiconductor module 10 in the Z direction of the mutually orthogonal XYZ axes shown in FIG. 1. Unless otherwise specified, “top view” refers to viewing the semiconductor module 10 from above along the Z-axis.

As shown in FIG. 1, the semiconductor module 10 includes a frame 11, a die mount 12, a plurality (seven in the first embodiment) of leads 13A to 13G, a first chip 14 mounted on the frame 11, and a second chip 15 mounted on the die mount 12, wires W1 to W11, and the sealing resin 16 sealing them. Herein, in this specification, the first chip 14 corresponds to the “semiconductor device” and the frame 11 corresponds to the “support member”.

The sealing resin 16 is formed, for example, in a rectangular flat plate shape with the Z direction as the thickness direction. The sealing resin 16 has first to fourth sealing side surfaces 16A to 16D. In the example shown in FIG. 1, the sealing resin 16 is formed into a rectangular shape in which the X direction becomes the long side direction and the Y direction becomes the short side direction in top view. The first sealing side surface 16A and the second sealing side surface 16B constitute both end surfaces of the sealing resin 16 in the X direction, and the third sealing side surface 16C and the fourth sealing side surface 16D constitute both end surfaces of the sealing resin 16 in the Y direction. In addition, the shape of the sealing resin 16 in top view can be arbitrarily changed. In one example, the shape of the sealing resin 16 in top view may also be a square.

The frame 11, the die mount 12, and the leads 13A to 13G are arranged in the X direction and spaced apart from each other. That is, the X direction becomes the arrangement direction of the frame 11, the die mount 12, and the leads 13A to 13G. In the example shown in FIG. 1, the arrangement direction of the frame 11, the die mount 12 and the leads 13A to 13G is consistent with the long side direction of the sealing resin 16. Therefore, it can also be said that the frame 11, the die mount 12, and the leads 13A to 13G are arranged in the long side direction of the sealing resin 16 and spaced apart from each other. The frame 11 is arranged closer to the first sealing side surface 16A than the die mount 12. The leads 13A to 13G are arranged closer to the second sealing side surface 16B than the die mount 12. That is, the die mount 12 is arranged between the frame 11 and the leads 13A to 13G in the X direction. The frame 11, the die mount 12, and the leads 13A to 13G are each made of metal materials, such as copper (Cu), aluminum (A1) and the like.

Herein, in the first embodiment, the frame 11, the die mount 12, and the leads 13A to 13G are each formed from a thin plate made of metals. The frame 11 mounts the first chip 14 and is electrically connected to the first chip 14. The die mount 12 carries the second chip 15, and the leads 13A to 13G are electrically connected to the second chip 15. Therefore, the frame 11 and the leads 13A to 13G are not limited to thin plates made of metals, as long as they are conductive layers. In addition, the die mount 12 is not limited to a conductive material such as a metal thin plate, but may also be a plate made of an insulating material. In other words, the die mount 12 only needs to be a supporting member that supports the second chip 15.

The frame 11 includes a die seat portion 11A and a lead portion 11B. In the first embodiment, the die seat portion 11A and the lead portion 11B are formed integrally.

The die seat portion 11A is a portion on which the first chip 14 is mounted and supports the first chip 14. The die seat portion 11A is disposed closer to the first sealing side surface 16A than the center of the sealing resin 16 in the X direction. On the other hand, the die seat portion 11A is located closer to the second sealing side surface 16B than the first sealing side surface 16A and is spaced apart in the X direction. The die seat portion 11A is formed in a rectangular flat plate shape with the Z direction as the thickness direction. The shape of the die seat portion 11A in top view is a rectangle in which the Y direction becomes the long side direction and the X direction becomes the short side direction. That is, the die seat portion 11A is formed so that the arrangement direction of the frame 11, the die mount 12, and the leads 13A to 13G becomes its short side direction. It can also be said that the die seat portion 11A is formed so that the long side direction of the sealing resin 16 becomes its short side direction.

The first chip 14 is mounted on the die seat portion 11A. More specifically, the first chip 14 is bonded to the die seat portion 11A using a conductive bonding material such as solder paste, silver (Ag) paste or the like. It can also be said that the first chip 14 is die-bonded to the die seat portion 11A. In this way, it can also be said that the first chip 14 is mounted on the frame 11.

The lead portion 11B is connected to a corner portion including an end portion close to the third sealing side surface 16C among both ends of the die seat portion 11A in the Y direction, and an end portion close to the first sealing side surface 16A among both ends of the die seat portion 11A in the X direction. In the example of FIG. 1, the lead portion 11B extends in the X direction from the die seat portion 11A toward the first sealing side surface 16A.

In addition, the structure of the frame 11 can be modified arbitrarily. For example, the die seat portion 11A and the lead portion 11B can be provided separately. In other words, the die seat portion 11A and the lead portion 11B may be arranged separately from each other. In this case, the die seat portion 11A is not limited to a metal thin plate (conductive layer) and may be formed of an insulating material. In other words, the die mount 12 only needs to be a supporting member that supports the first chip 14.

The die mount 12 is a portion that mounts the second chip 15 and supports the second chip 15. The shape of the die mount 12 in top view is a rectangle in which the Y direction becomes the long side direction and the X direction becomes the short side direction. Therefore, the long side direction of the die mount 12 is consistent with the long side direction of the die seat portion 11A of the frame 11, and the short side direction of the die mount 12 is consistent with the short side direction of the die seat portion 11A. In other words, the die mount 12 is formed so that the arrangement direction of the frame 11, the die mount 12, and the leads 13A to 13G becomes its short side direction. It can also be said that the die mount 12 is formed so that the long side direction of the sealing resin 16 becomes its short side direction.

The second chip 15 is mounted on the die mount 12. More specifically, the second chip 15 is bonded to the die mount 12 using a conductive bonding material such as solder paste, silver paste or the like. It can also be said that the second chip 15 is die-bonded to the die mount 12.

The lead 13A and the leads 13B to 13G are dispersedly arranged at both ends of the sealing resin 16 in the X direction. More specifically, the lead 13A is disposed at an end close to the first sealing side surface 16A among both ends of the sealing resin 16 in the X direction. The leads 13B to 13G are each arranged at an end close to the second sealing side surface 16B among both ends of the sealing resin 16 in the X direction. In the first embodiment, the lead 13A is disposed at a position overlapping an end close to the fourth sealing side surface 16D among both ends of the die seat portion 11A in the Y direction when viewed from the X direction. The lead 13A is closer to the first sealing side surface 16A than the die seat portion 11A, and is arranged apart from the die seat portion 11A.

The leads 13B to 13G are aligned with each other in the X direction and are arranged apart from each other in the Y direction. The leads 13B to 13G are arranged in the order of the lead 13B, the lead 13C, the lead 13D, the lead 13E, the lead 13F and the lead 13G from the fourth sealing side 16D to the third sealing side 16C. As can be seen from FIG. 1, the distance in the Y direction between the lead 13A and the lead portion 11B is greater than the distance in the Y direction between adjacent leads among the leads 13B to 13G.

The first chip 14 mounted on the die seat portion 11A is formed in a rectangular flat plate shape with the Z direction as the thickness direction. The shape of the first chip 14 in top view is a rectangle in which the Y direction becomes the long side direction and the X direction becomes the short side direction. That is, the long side direction of the first chip 14 coincides with the long side direction of the die seat portion 11A, and the short side direction of the first chip 14 coincides with the short side direction of the die seat portion 11A. Therefore, the first chip 14 is arranged so that its short side direction coincides with the arrangement direction of the frame 11, the die mount 12, and the leads 13A to 13G. It can also be said that the first chip 14 is arranged so that its short side direction coincides with the long side direction of the sealing resin 16. In addition, the shape and arrangement of the first chip 14 in top view can be arbitrarily changed. In addition, the number of terminals of the first chip 14 can be changed arbitrarily. In addition, the arrangement positions of terminals P1 to P5 can be changed arbitrarily. In one example, at least one of the terminal P1 and the terminal P2 may be arranged at an end close to the second chip 15 among both ends of the first chip 14 in the X direction.

The first chip 14 includes a plurality of terminals P1 to P5. The terminals P1 to P5 are formed to be exposed from the chip surface of the first chip 14. The terminals P1 and P2 are provided at the end close to the first sealing side surface 16A among both ends of the chip surface in the X direction. The terminal P1 is provided near the lead 13A on the chip surface. The terminal P2 is provided near the lead portion 11B on the chip surface. The terminals P3 to P5 are provided at the end close to the second chip 15 among both ends of the chip surface in the X direction. The terminals P3 to P5 are arranged apart from each other in the Y direction. In addition, the number of terminals of the first chip 14 can be changed arbitrarily.

The second chip 15 mounted on the die mount 12 is formed in a rectangular flat plate shape with the Z direction as the thickness direction. The shape of the second chip 15 in top view is a rectangle with the Y direction being the long side direction and the X direction being the short side direction. That is, the long side direction of the second chip 15 is consistent with the long side direction of the die mount 12, and the short side direction of the second chip 15 is consistent with the short side direction of the die mount 12. Therefore, the second chip 15 is arranged so that its short side direction coincides with the arrangement direction of the frame 11, the die mount 12, and the leads 13A to 13G. It can also be said that the second chip 15 is arranged so that its short side direction coincides with the long side direction of the sealing resin 16. In addition, the shape and arrangement of the second chip 15 in top view can be arbitrarily changed.

The second chip 15 includes a plurality of terminals Q1 to Q9. The plurality of terminals Q1 to Q9 is formed to be exposed from the chip surface of the second chip 15. The terminals Q1 to Q3 are provided at the end close to the first chip 14 among both ends of the chip surface in the X direction. The terminals Q1 to Q3 are arranged apart from each other in the Y direction. The terminals Q4 to Q9 are provided at the end close to the second sealing side surface 16B (leads 13B to 13G) among both ends of the chip surface in the X direction. The terminals Q4 to Q9 are arranged apart from each other in the Y direction. In addition, the number of terminals of the second chip 15 can be changed arbitrarily.

The terminal P1 of the first chip 14 is electrically connected to the lead 13A through the wire W1. The terminal P2 is electrically connected to the lead portion 11B through the wire W2. Therefore, it can also be said that the terminal P2 is electrically connected to the frame 11. The lead 13A and the lead portion 11B are electrically connected to the high voltage generating unit VT. The high voltage generating unit VT is, for example, a DC power supply. The positive electrode of the high voltage generating unit VT is electrically connected to the lead 13A, and the negative electrode of the high voltage generating unit VT is electrically connected to the lead portion 11B.

The terminals P3 to P5 of the first chip 14 are electrically connected to the terminals Q1 to Q3 of the second chip 15 via wires W3 to W5 respectively. The terminals Q4 to Q9 are electrically connected to the leads 13B to 13G via the wires W6 to W11 respectively.

Herein, in the first embodiment, among the terminals P1 to P5, the terminals P1 and P2 constitute the high-voltage side terminals, and the terminals P3 to P5 constitute the low-voltage side terminals. In other words, among the terminals P1 to P5 of the first chip 14, the terminals electrically connected to the lead 13A and the lead portion 11B constitute the high-voltage side terminals, and the terminals electrically connected to the second chip 15 constitute the low-voltage side terminals.

In this way, the die seat portion 11A of the frame 11 electrically connected to the high voltage generating unit VT constitutes a high-voltage side die seat, and the die mount 12 constitutes a low-voltage side die seat. Therefore, the insulation withstand voltage of the terminals P3 to P5 and the substrate 30 of the first chip 14 is higher than the insulation withstand voltage of the terminals P1 and P2 and the substrate 30. In one example, the insulation withstand voltage between the terminals P3 to P5 and the substrate 30 is about 3,850 V in terms of DC voltage, and the insulation withstand voltage between the terminals P1 and P2 and the substrate 30 is about 1,400 V in terms of DC voltage.

Next, the circuit configuration in the first chip 14 and the second chip 15 will be described.

As shown in FIG. 2, the first chip 14 includes the first to fourth resistance circuits 14A to 14D for reducing the high voltage of the high voltage generating unit VT (referring to FIG. 1). The first resistance circuit 14A includes a resistance value RA, the second resistance circuit 14B includes a resistance value RB, the third resistance circuit 14C includes a resistance value RC, and the fourth resistance circuit 14D includes a resistance value RD.

The resistance value RB is less than the resistance value RA. The ratio of the resistance value RB to the resistance value RA (RB/RA) is set in advance. The resistance value RC is less than the resistance value RD. The ratio of the resistance value RC to the resistance value RD (RC/RD) is set in advance. The ratio (RB/RA) and the ratio (RC/RD) are set to the same specified value (for example, 1/999).

The first to fourth resistance circuits 14A to 14D are connected in series. Each of the first to fourth resistance circuits 14A to 14D has a first end and a second end. The first end of the first resistance circuit 14A is electrically connected to the terminal P1, and the second end of the first resistance circuit 14A is electrically connected to the first end of the second resistance circuit 14B. The connection point between the first resistance circuit 14A and the second resistance circuit 14B is electrically connected to the terminal P3. The second end of the second resistance circuit 14B is electrically connected to the first end of the third resistance circuit 14C. The connection point between the second resistance circuit 14B and the third resistance circuit 14C is electrically connected to the terminal P4. The second end of the third resistance circuit 14C is electrically connected to the first end of the fourth resistance circuit 14D. The connection point between the third resistance circuit 14C and the fourth resistance circuit 14D is electrically connected to the terminal P5. The second end of the fourth resistance circuit 14D is electrically connected to the terminal P2.

The second chip 15 includes a voltage detection circuit 15A. The voltage detection circuit 15A includes an operational amplifier. The voltage detection circuit 15A is electrically connected to terminals Q1 to Q3. The terminal Q1 is electrically connected to the terminal P3 of the first chip 14 through the wire W3, the terminal Q2 is electrically connected to the terminal P4 of the first chip 14 through the wire W4, and the terminal Q3 is electrically connected to the terminal P5 of the first chip 14 through the wire W5. Therefore, the voltage detection circuit 15A is configured to detect the voltage between the connection point between the first resistance circuit 14A and the second resistance circuit 14B, the connection point between the second resistance circuit 14B and the third resistance circuit 14C, and the connection point between the third resistance circuit 14C and the fourth resistance circuit 14D. The terminals Q4 to Q9 (leads 13B to 13G (referring to FIG. 1)) are used to supply the power supply voltage to the operational amplifier in the second chip 15 or output the output signal from the voltage detection circuit 15A.

### [Schematic Planar Structure of the First Chip]

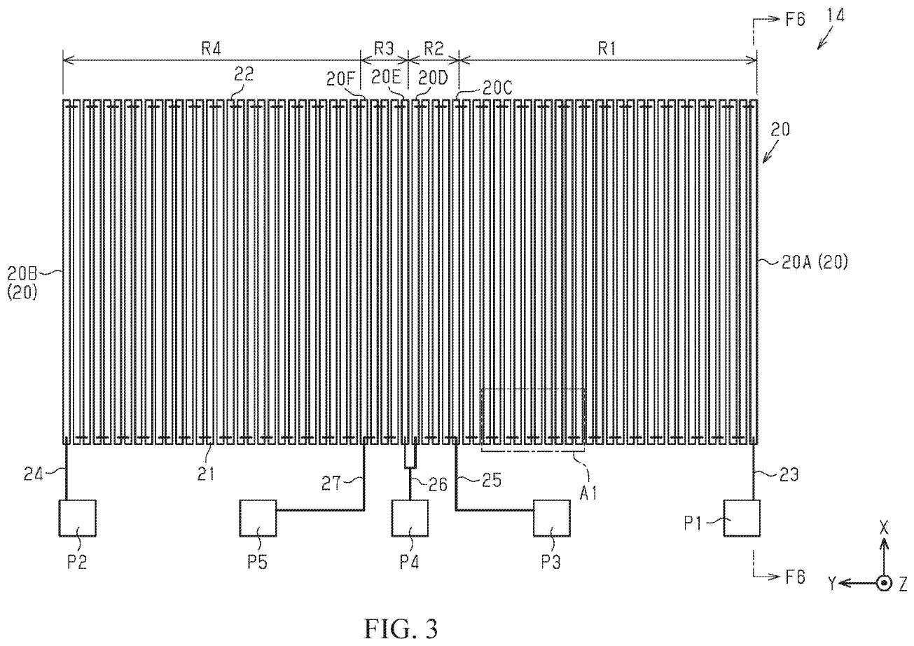

FIG. 3 shows an example of the schematic planar structure of the first chip 14 including the first to fourth resistance circuits 14A to 14D (referring FIG. 2). In addition, in FIG. 3, in order to facilitate understanding of the drawing, an example in which the terminals P1 and P2 are arranged on the same side as the terminals P3 to P5 is shown. The terminals P1 and P2 may be arranged on the opposite side of the first chip 14 from the terminals P3 to P5 in the X direction as shown in FIG. 1.

As shown in FIG. 3, the first chip 14 includes a plurality of unit semiconductor resistive layers (hereinafter, “semiconductor resistive layers 20”). Each semiconductor resistive layer 20 extends along the X direction in top view. In other words, each semiconductor resistive layer 20 extends along the short side direction of the first chip 14 in top view. In top view, the plurality of semiconductor resistive layers 20 are aligned with each other in the X direction and arranged apart from each other in the Y direction. In other words, in top view, the plurality of semiconductor resistive layers 20 are aligned with each other in the short side direction of the first chip 14 and are arranged apart from each other in the long side direction of the first chip 14. The plurality of semiconductor resistive layers 20 are electrically connected in series.

The terminal P1 is electrically connected to the semiconductor resistive layer 20A, which is the semiconductor resistive layer arranged at the first end in the Y direction among the plurality of semiconductor resistive layers 20. The terminal P2 is electrically connected to the semiconductor resistive layer 20B, which is the semiconductor resistive layer disposed at the second end on the side opposite to the first end in the Y direction among the plurality of semiconductor resistive layers 20. The terminal P1 and the semiconductor resistive layer 20A are electrically connected through the wiring layer 23. The terminal P2 and the semiconductor resistive layer 20B are electrically connected through the wiring layer 24.

The plurality of semiconductor resistive layers 20 serve as components of the first to fourth resistance circuits 14A to 14D. The plurality of semiconductor resistive layers 20 can be divided into the first to fourth resistance regions R1 to R4 in the Y direction as a plurality of resistance regions. That is, the first to fourth resistance regions R1 to R4 are regions divided in the long side direction of the first chip 14. The first resistance region R1 is a region including a plurality of semiconductor resistance layer 20 at the first end in the Y direction. In other words, the first resistance region R1 is a Y-direction end region including the semiconductor resistive layer 20A. The fourth resistance region R4 is a region including a plurality of semiconductor resistive layers 20 at the second end in the Y-direction. In other words, the fourth resistance region R4 is a Y-direction end region including the semiconductor resistive layer 20B. The portion of the plurality of semiconductor resistive layers 20 arranged between the first resistance region R1 and the fourth resistance region R4 in the Y direction is divided by the second resistance region R2 and the third resistance region R3. The second resistance region R2 is the region adjacent to the first resistance region R1, and the third resistance region R3 is the region adjacent to the fourth resistance region R4. Therefore, the first to fourth resistance regions R1 to R4 are arranged in the order of the resistance regions R1, R2, R3, and R4 from the first end (the semiconductor resistance layer 20A) to the second end (the semiconductor resistance layer 20B) of the plurality of semiconductor resistance layers 20. The first resistance region R1 is a region constituting the first resistance circuit 14A, the second resistance region R2 is a region constituting the second resistance circuit 14B, the third resistance region R3 is a region constituting the third resistance circuit 14C, and the fourth resistance region R4 is a region constituting the fourth resistance circuit 14D.

The terminal P3 is electrically connected to the semiconductor resistive layer 20C at one end close to the first resistance region R1 among the plurality of semiconductor resistive layers 20 in the second resistance region R2. The terminal P3 and the semiconductor resistive layer 20C are electrically connected through the wiring layer 25.

The terminal P4 is electrically connected to the semiconductor resistive layer 20D at one end close to the third resistance region R3 among the plurality of semiconductor resistive layers 20 in the second resistance region R2 and the semiconductor resistive layer 20E at one end close to the second resistance region R2 among the plurality of semiconductor resistive layers 20 in the third resistance region R3. The terminal P4 and the semiconductor resistive layers 20D and 20E are electrically connected through the wiring layer 26.

The terminal P5 is electrically connected to the semiconductor resistive layer 20F at one end close to the fourth resistance region R4 among the plurality of semiconductor resistive layers 20 in the third resistance region R3. The terminal P5 and the semiconductor resistive layer 20F are electrically connected through the wiring layer 27.

The number of semiconductor resistive layers 20 in each of the first to fourth resistance regions R1 to R4 is set individually. In the first embodiment, the first resistance region R1 and the fourth resistance region R4 have the same number of semiconductor resistive layers 20, and the second resistance region R2 and the third resistance region R3 have the same number of semiconductor resistive layers 20. Furthermore, the number of the semiconductor resistive layers 20 in each of the first resistance region R1 and the fourth resistance region R4 is more than the number of the semiconductor resistive layers 20 in each of the second resistance region R2 and the third resistance region R3. In addition, the number of the semiconductor resistive layers 20 in each of the first to fourth resistance regions R1 to R4 is not limited to the first embodiment, and can be changed arbitrarily.

### [Cross-Sectional Structure of the First Chip]

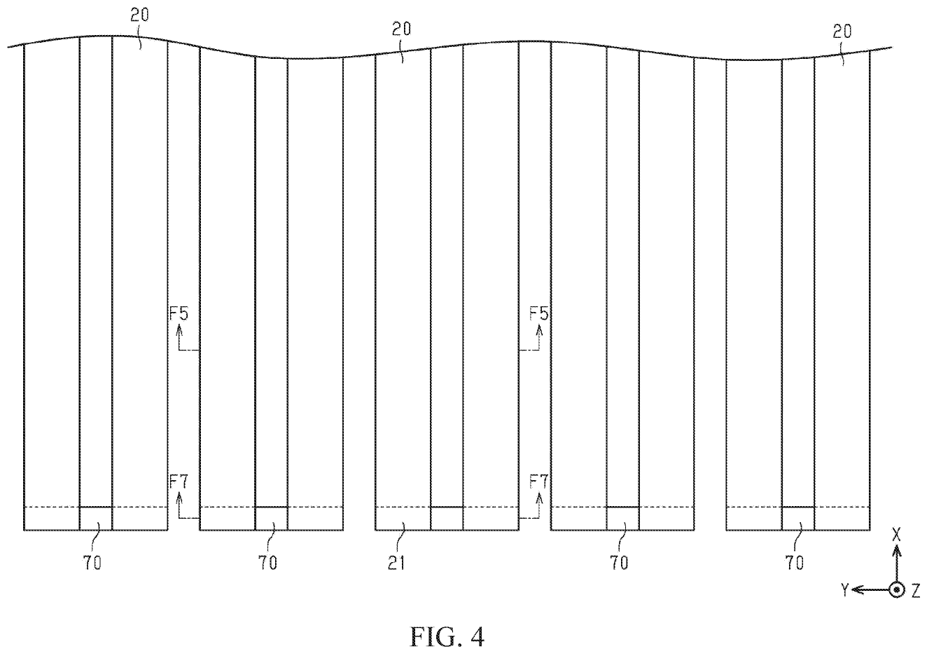

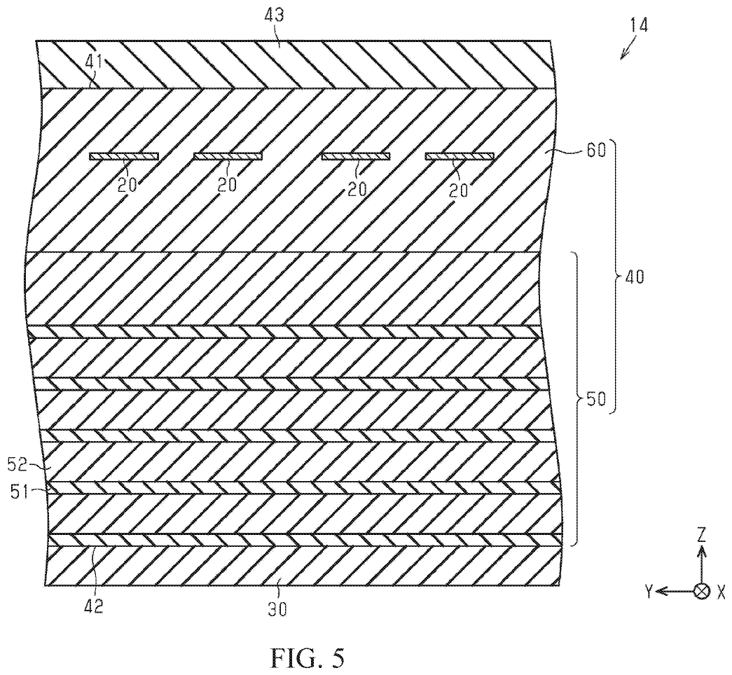

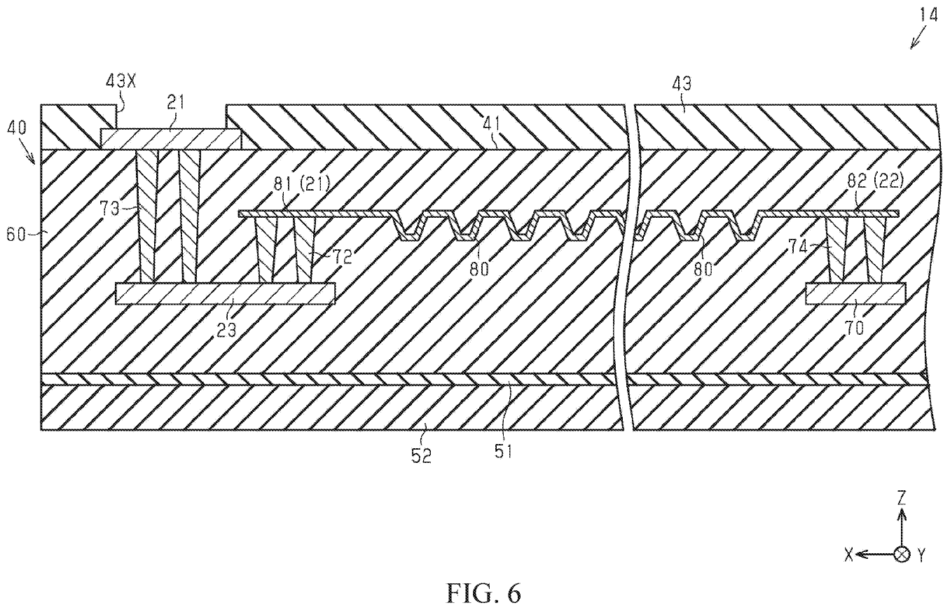

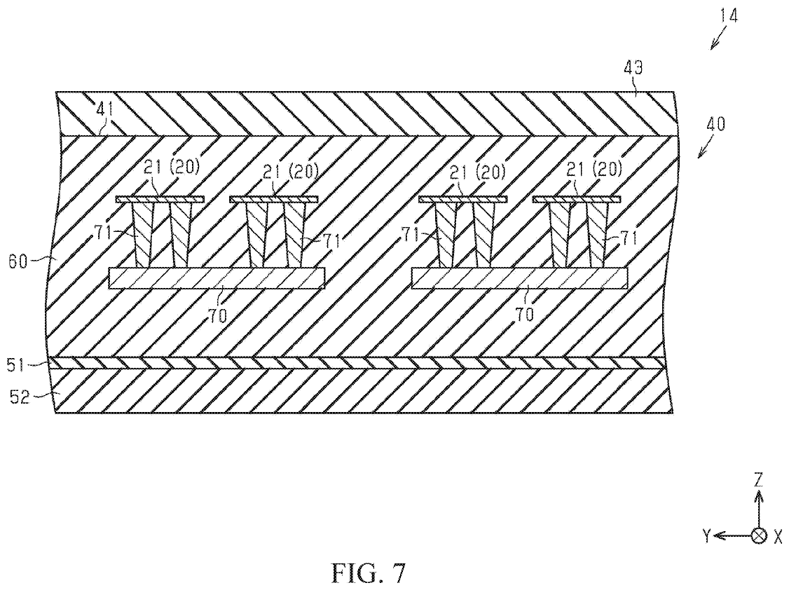

An example of the internal structure of the first chip 14 will be described with reference to FIGS. 4 to 7. FIG. 4 is an enlarged top view of the frame A1 shown by the one-dot chain line in FIG. 3. FIG. 5 schematically shows the cross-sectional structure of the first chip 14 taken along line F5-F5 in FIG. 4. FIG. 6 schematically shows the cross-sectional structure of the first chip 14 taken along line F6-F6 in FIG. 3. FIG. 7 shows a portion of the cross-sectional structure of the first chip 14 taken along line F7-F7 in FIG. 4. In addition, in FIG. 5, for ease of illustration, an interface between a substrate-side insulating layer 50 and a surface-side insulating layer 60 described below is shown. In fact, the interface between the substrate-side insulating layer 50 and the surface-side insulating layer 60 may not be visually recognized. In addition, in FIGS. 6 and 7, a portion of the substrate-side insulating layer 50 and the substrate 30 are omitted.

As shown in FIG. 5, the first chip 14 includes a substrate 30 and an element insulating layer 40 formed on the substrate 30.

The substrate 30 is, for example, a semiconductor substrate formed of a material containing Si (silicon). The thickness of the substrate 30 is, for example, about 300 μm. In addition, a wide band gap semiconductor or a compound semiconductor may be used for the substrate 30. The wide band gap semiconductor is a semiconductor substrate with a band gap of 2.0 eV or more. The wide band gap semiconductor may be SiC (silicon carbide). The compound semiconductor may be the III-V compound semiconductor. The compound semiconductor may include at least one of AlN (aluminum nitride), InN (indium nitride), GaN (gallium nitride), and GaAs (gallium arsenide).

The element insulating layer 40 has an element front surface 41 and an element back surface 42 facing opposite sides in the Z direction. Herein, in the first embodiment, the Z direction corresponds to “the thickness direction of the element insulating layer”. The element back surface 42 is in contact with the substrate 30. The element front surface 41 is the surface opposite to the substrate 30 in the Z direction.

As shown in FIG. 6, the terminals P1 to P5 (referring to FIG. 3) and a passivation film 43 are formed on the element insulating layer 40.

The terminals P1 to P5 are formed on the element front surface 41 of the element insulating layer 40. The terminals P1 to P5 are appropriately selected from one or more of Ti (titanium), TiN (titanium nitride), Ta (tantalum), TaN (tantalum nitride), Au (gold), Ag, Cu, Al, Ni (nickel), Pd (palladium) and W (tungsten). In the first embodiment, the terminals P1 to P5 are formed of a material containing A1. As an example, FIG. 6 shows a structure in which the terminal P1 is formed on the element front surface 41.

As shown in FIG. 6, the terminal P1 is covered with the passivation film 43. On the other hand, the passivation film 43 has an opening 43X exposing the terminal P1. In addition, although not shown in the figure, the relationship between the terminals P2 to P5 and the passivation film 43 is also the same as the relationship between the terminal P1 and the passivation film 43. In this way, the terminals P1 to P5 constitute the electrode pads.

The passivation film 43 formed on the element front surface 41 of the element insulating layer 40 is a surface protective film of the first chip 14. The passivation film 43 is formed of a material containing SiN, for example. In addition, the material constituting the passivation film 43 can be arbitrarily changed, and may be formed of a material containing SiO₂ (silicon dioxide), for example. In addition, the passivation film 43 may have a laminated structure of a plurality of films, for example, a laminated structure of a film formed of a material containing SiN and a film formed of a material containing SiO₂.

The element insulating layer 40 includes a substrate-side insulating layer 50 provided on the substrate 30 and a surface-side insulating layer 60 laminated on the substrate-side insulating layer 50.

The substrate-side insulating layer 50 is, for example, an insulating layer for improving the insulation withstand voltage of the first chip 14. The substrate-side insulating layer 50 is an insulating layer including the element back surface 42 of the element insulating layer 40. Therefore, the substrate-side insulating layer 50 is in contact with the substrate 30.

The substrate-side insulating layer 50 has a plurality of etching stop films 51 and a plurality of interlayer insulating films 52 formed on the plurality of etching stop films 51. The plurality of etching stop films 51 and the plurality of interlayer insulating films 52 are alternately stacked one by one in the Z direction. Herein, the etching stop film 51 corresponds to “the first insulating film”, and the interlayer insulating film 52 corresponds to “the second insulating film”.

The etching stop film 51 is formed of a material containing SiN (silicon nitride), SiC, SiCN (nitrogen-doped silicon carbide), or the like. In the first embodiment, the etching stop film 51 is formed of a material containing SiN.

The interlayer insulating film 52 is an insulating film that relieves the stress of the etching stop film 51. The interlayer insulating film 52 is an oxide film formed of a material containing SiO₂ (silicon dioxide), for example. The film thickness of the interlayer insulating film 52 is thicker than the film thickness of the etching stop film 51. The etching stop film 51 has a thickness of 50 nm or more and 1000 nm or less. The interlayer insulating film 52 has a thickness of 500 nm or more and 5000 nm or less. In the first embodiment, the etching stop film 51 has a thickness of approximately 300 nm, and the interlayer insulating film 52 has a thickness of approximately 2000 nm. In addition, from the viewpoint of ease of viewing the drawings, the ratio of the film thickness of the etching stop film 51 to the film thickness of the interlayer insulating film 52 in the drawing is different from the actual ratio of the film thickness of the etching stop film 51 to the film thickness of the interlayer insulating film 52.

The surface-side insulating layer 60 is in contact with the uppermost interlayer insulating film 52 of the substrate-side insulating layer 50. The thickness of the surface-side insulating layer 60 is more than the total thickness of one etching stop film 51 and one interlayer insulating film 52. The surface-side insulating layer 60 is formed of a material containing SiO₂ (silicon dioxide), for example.

As shown in FIG. 5, a plurality of semiconductor resistive layers 20 is provided in the element insulating layer 40. In the first embodiment, the plurality of semiconductor resistive layers 20 is provided on the substrate-side insulating layer 50. The plurality of semiconductor resistive layers 20 is covered with the surface-side insulating layer 60. Therefore, it can also be said that the plurality of semiconductor resistive layers 20 is embedded in the element insulating layer 40. In this way, it can be said that the first chip 14 includes the semiconductor resistive layers 20 provided on the substrate-side insulating layer 50 and the surface-side insulating layer 60 covering the semiconductor resistive layers 20.

In one example, the plurality of semiconductor resistive layers 20 are arranged closer to the element front surface 41 than the substrate-side insulating layer 50 in the Z direction and separate from the substrate-side insulating layer 50. Therefore, a portion of the surface-side insulating layer 60 is interposed between each semiconductor resistive layer 20 and the substrate-side insulating layer 50 in the Z direction. Therefore, it can also be said that each semiconductor resistive layer 20 is embedded in the surface-side insulating layer 60.

The semiconductor resistive layer 20 is formed in a flat plate shape with the Z direction as the thickness direction. The thickness of the semiconductor resistive layer 20 is thinner than the width (Y-direction length) of the semiconductor resistive layer 20. The thickness of the semiconductor resistive layer 20 is, for example, 1 nm or more and 100 nm or less. In the first embodiment, the thickness of the semiconductor resistive layer 20 is approximately 2.5 nm. It can be said that the semiconductor resistive layer 20 has a thinner thickness than the interlayer insulating film 52. The semiconductor resistive layer 20 may have a thickness thinner than the etching stop film 51. The semiconductor resistive layer 20 is formed of a material containing CrSi (chromium silicon), for example.

Each semiconductor resistive layer 20 includes a first resistive end portion 21 and a second resistive end portion 22. The first resistive end portion 21 is an end portion on the side where the terminal P1 is located among both end portions of each semiconductor resistive layer 20 in the X direction. The second resistive end portion 22 is an end portion on the opposite side to the side where the terminal P1 is located, among both end portions of each semiconductor resistive layer 20 in the X direction. The plurality of semiconductor resistive layers 20 are electrically connected alternately at the first resistive end portion 21 and the second resistive end portion 22.

As shown in FIG. 7, the semiconductor resistive layers 20 adjacent in the Y direction are electrically connected through wiring layers 70. As shown in FIGS. 3 and 7, the wiring layer 70 is disposed at a position overlapping the first resistive end portion 21 of the semiconductor resistive layer 20 in top view. As shown in FIG. 7, the wiring layer 70 is arranged at a different position from the semiconductor resistive layer 20 in the Z direction. The wiring layer 70 is arranged closer to the substrate 30 (referring to FIG. 5) than the semiconductor resistive layer 20 in the Z direction. On the other hand, the wiring layer 70 is provided on the substrate-side insulating layer 50. Therefore, the wiring layer 70 is arranged between the semiconductor resistive layer 20 and the substrate-side insulating layer 50 in the Z direction. That is, it can also be said that the wiring layer 70 is embedded in the surface-side insulating layer 60.

The wiring layer 70 and the semiconductor resistive layer 20 are connected through a connecting wiring 71. That is, the first chip 14 includes the connecting wiring 71 that connects the semiconductor resistive layer 20 and the wiring layer 70. The connecting wiring 71 is connected to a portion of the wiring layer 70 that overlaps the first resistive end portion 21 of the semiconductor resistive layer 20 in top view. An example of the connecting wiring 71 is a through hole. One semiconductor resistive layer 20 is connected to the wiring layer 70 through a plurality of connecting wirings 71. Each connecting wiring 71 extends along the Z direction.

The wiring layer 23 that electrically connects the terminal P1 to the semiconductor resistive layer 20A is disposed at the same position as the wiring layer 70 in the Z direction, for example. The wiring layer 23 is arranged at a position different from the wiring layer 70 in the Y direction at the first resistive end portion 21 of the semiconductor resistive layer 20A, for example. In other words, the first resistive end portion 21 of the semiconductor resistive layer 20A is not electrically connected by the wiring layer 70. In addition, the wiring layers 24 to 27 (referring to FIG. 3) that respectively connect the terminals P2 to P5 to the semiconductor resistive layers 20 are also arranged at the same position as the wiring layer 23 in the Z direction. The connection structures between the terminals P2 to P5 and the semiconductor resistive layers 20 are substantially the same as the connection structure between the terminal P1 and the semiconductor resistive layer 20, so detailed description thereof is omitted.

In top view, the wiring layer 23 includes a portion overlapping the first resistive end portion 21 of the semiconductor resistive layer 20A and a portion extending in the X direction from the first resistive end portion 21. The portion of the wiring layer 23 extending in the X direction from the first resistive end portion 21 includes a portion that overlaps the terminal P1 in top view.

The wiring layer 23 and the semiconductor resistive layer 20A are connected by the connecting wiring for resistive layer 72. That is, the first chip 14 includes the connecting wiring for resistive layer 72 that connects the wiring layer 23 with the semiconductor resistive layer 20A. The connecting wiring for resistive layer 72 is connected to a portion of the wiring layer 23 that overlaps the first resistive end portion 21 of the semiconductor resistive layer 20A in top view. An example of the connecting wiring for resistive layer 72 is a through hole. The semiconductor resistive layer 20A and the wiring layer 23 are connected through a plurality of connecting wirings for resistive layer 72. Each connecting wiring for resistive layer 72 extends along the Z direction.

The wiring layer 23 and the terminal P1 are connected by the connecting wiring for terminal 73. That is, the first chip 14 includes the connecting wiring for terminal 73 that connects the wiring layer 23 and the terminal P1. The connecting wiring for terminal 73 is connected to a portion of the wiring layer 23 that overlaps the terminal P1 in top view. An example of the connecting wiring for terminal 73 is a through hole. The terminal P1 and the wiring layer 23 are connected by a plurality of connecting wirings for terminal 73. Each connecting wiring for terminal 73 extends in the Z direction.

As shown in FIG. 6, the wiring layer 70 is also disposed at a position overlapping the second resistive end portion 22 of the semiconductor resistive layer 20 in top view. The wiring layer 70 and the second resistive end portion 22 of the semiconductor resistive layer 20 are connected by a connecting wiring 74. An example of the connecting wiring 74 is a through hole. The second resistive end portion 22 of the semiconductor resistive layer 20 are connected with the wiring layer 70 through a plurality of connecting wirings 74. Each connecting wiring 74 extends along the Z direction.

In this way, the adjacent semiconductor resistive layers 20 in the Y direction are connected in series by arranging the wiring layer 70 and the connecting wiring 71 at a position overlapping the first resistive end portion 21 of the semiconductor resistive layer 20 in top view and arranging the wiring layer 70 and the connecting wiring 74 at a position overlapping the second resistive end portion 22 of the semiconductor resistive layer 20 in top view.

The wiring layer 70 is formed of a material containing at least one of Ti, TiN, Ta, TaN, Au, Ag, Cu, Al, and W, for example. In one example, the wiring layer 70 is formed of a material containing A1. In one example, the wiring layer 70 is an A1 layer formed of A1.

The connecting wirings 71 and 74 are formed of a material containing at least one of Ti, TiN, Ta, TaN, Au, Ag, Cu, Al, and W, for example. In one example, the connecting wiring 71 is formed of a material containing W. The connecting wiring for resistive layer 72 is formed of a material containing at least one of Ti, TiN, Ta, TaN, Au, Ag, Cu, Al, and W, for example. In one example, the connecting wiring for resistive layer 72 is formed of the same material as the connecting wirings 71 and 74. In one example, the connecting wiring for resistive layer 72 is formed of a material containing W. The connecting wiring for terminal 73 is formed of a material including at least one of Ti, TiN, Ta, TaN, Au, Ag, Cu, Al, and W, for example. In one example, the terminal connecting wire 73 is formed of the same material as the connecting wires 71 and 74. In one example, the connecting wiring for terminal 73 is formed of a material containing W.

### [Detailed Structure of Semiconductor Resistive Layer]

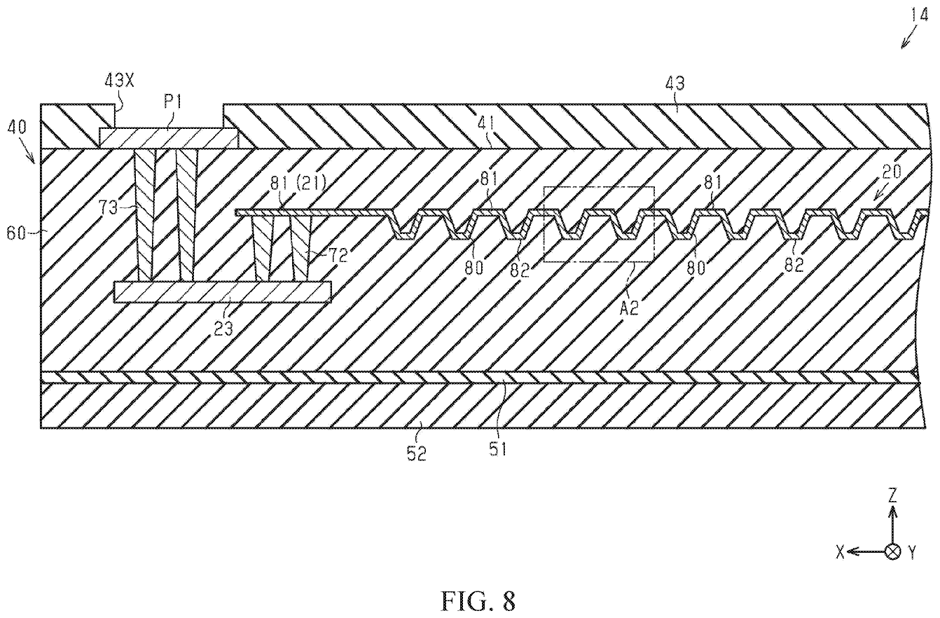

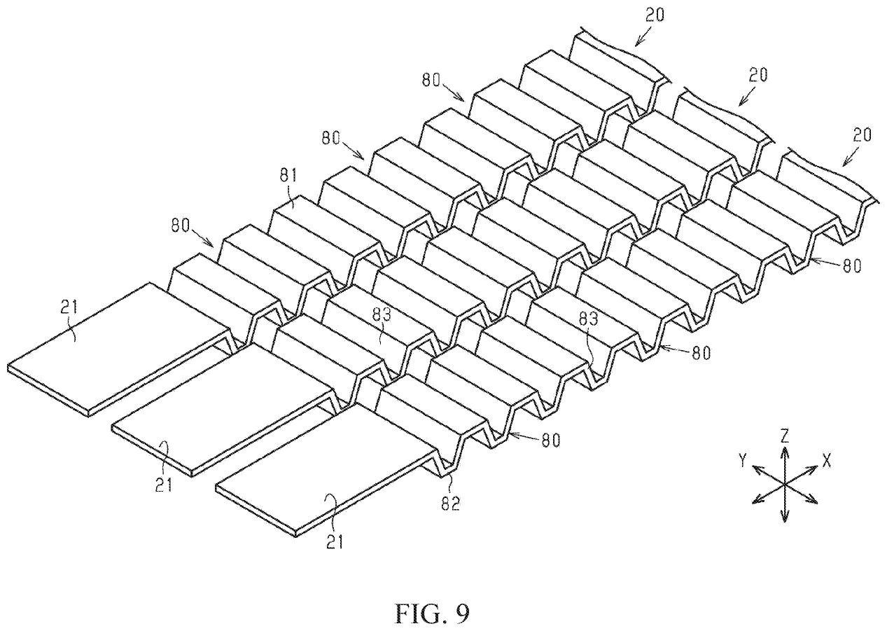

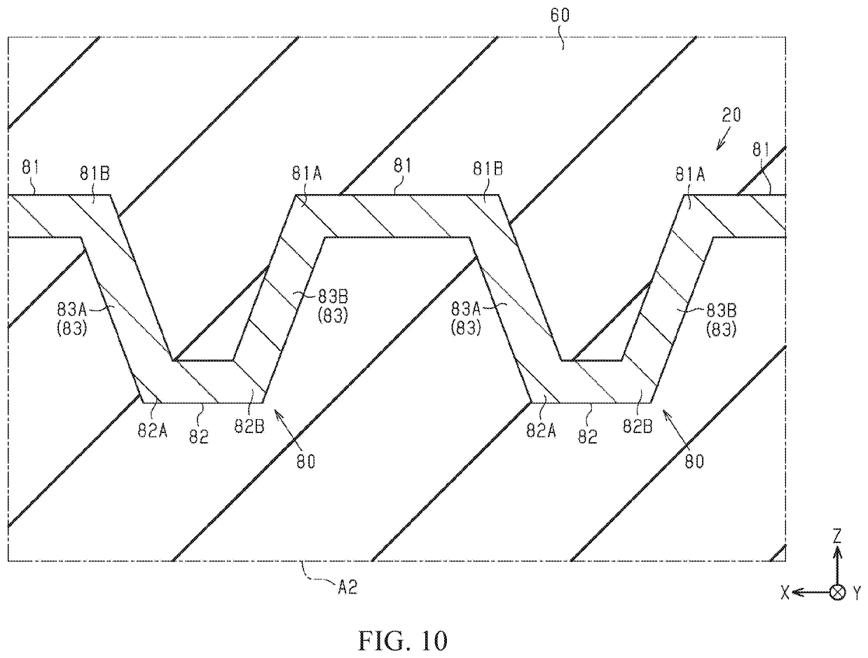

The detailed structure of the semiconductor resistive layer 20 will be described with reference to FIG. 6 and FIGS. 8 to 10. FIG. 8 is an enlarged view of the first resistive end portion 21 and its surroundings in the semiconductor resistive layer 20 of FIG. 6. FIG. 9 shows a schematic three-dimensional structure of the semiconductor resistive layer 20. FIG. 10 is an enlarged view of the frame A2 of the one-dot chain line in FIG. 8.

As shown in FIG. 8, the semiconductor resistive layer 20 extends along the first direction orthogonal to the thickness direction of the substrate 30 (referring to FIG. 5), and has an uneven portion 80 in the thickness direction. In the first embodiment, the semiconductor resistive layer 20 extends in the X direction and has the uneven portion 80 in the Z direction. Therefore, the X direction corresponds to “the first direction” and the Z direction corresponds to “the thickness direction of the substrate”.

As shown in FIG. 9, in the first embodiment, a plurality of uneven portions 80 are spaced apart from each other in the X direction. In the first embodiment, the plural uneven portions 80 are provided at equal intervals in the X direction. In addition, the arrangement form of the plurality of uneven portions 80 can be changed arbitrarily. In one example, at least a portion of the plurality of uneven portions 80 may be arranged at unequal intervals. In the example of FIG. 9, the X-direction positions of the uneven portions 80 in the semiconductor resistive layers 20 adjacent in the Y-direction are the same as each other.

As shown in FIG. 6, the semiconductor resistive layer 20 includes the first resistive end portion 21 and the second resistive end portion 22. Both the first resistive end portion 21 and the second resistive end portion 22 are not provided with the uneven portion 80 and extend along the X direction when viewed from the Y direction. In other words, both the first resistive end portion 21 and the second resistive end portion 22 are provided at positions different from the uneven portions 80 in the X direction. Herein, the Y direction corresponds to “the second direction”.

The Z-direction position of the first resistive end portion 21 and the Z-direction position of the second resistive end portion 22 are the same as each other. The thickness of the first resistive end portion 21 and the thickness of the second resistive end portion 22 are equal to each other. Herein, as long as the difference between the thickness of the first resistive end portion 21 and the thickness of the second resistive end portion 22 is, for example, 10% or less of the thickness of the first resistive end portion 21, it can be said that the thickness of the first resistive end portion 21 and the thickness of the second resistive end portion 22 are equal to each other.

As shown in FIG. 10, the uneven portion 80 includes a first resistive portion 81, a second resistive portion 82, and a connecting portion 83. In one example, the first resistive portion 81, the second resistive portion 82, and the connecting portion 83 are formed integrally.

When viewed from the Y direction, the first resistive portion 81 extends along the X direction. The Z-direction position of the first resistive portion 81 is the same as the Z-direction position of the first resistive end portion 21 and the second resistive end portion 22 (both referring to FIG. 6). The first resistive portion 81 includes a first end portion 81A and a second end portion 81B as both ends in the X direction. The first end portion 81A is an end portion of the first resistive portion 81 close to the first resistive end portion 21 in the X direction. The second end portion 81B is an end portion of the first resistive portion 81 close to the second resistive end portion 22 in the X direction.

The plurality of first resistive portions 81 of the plurality of uneven portions 80 are arranged at the same positions in the Z direction. The plurality of first resistive portions 81 are arranged in the X direction and spaced apart from each other.

As shown in FIG. 8, the first resistive portion 81 of the uneven portions 80 closest to the first resistive end portion 21 among the plurality of uneven portions 80 constitutes the first resistive end portion 21. That is, the X-direction length of the first resistive portion 81 of the uneven portion 80 closest to the first resistive end portion 21 among the plurality of uneven portions 80 is longer than the lengths of the other first resistive portions 81. The thickness of the first resistive portion 81 is equal to the thickness of the first resistive end portion 21. Herein, as long as the difference between the thickness of the first resistive portion 81 and the thickness of the first resistive end portion 21 is, for example, within 10% of the thickness of the first resistive end portion 21, it can be said that the thickness of the first resistive portion 81 is the same as that of the first resistive end portion 21.

The second resistive portion 82 is provided at a position shifted from the first resistive portion 81 in the X direction and the Z direction. That is, the second resistive portion 82 is disposed at a position (a different position) that does not overlap the first resistive portion 81 in the Y direction in top view. In the first embodiment, the second resistive portion 82 is arranged closer to the substrate 30 (referring to FIG. 5) than the first resistive portion 81 in the Z direction. In one example, the second resistive portion 82 is arranged closer to the first resistive portion 81 than the wiring layer 70 in the Z direction. Therefore, it can be said that the second resistive portion 82 is arranged between the first resistive portion 81 and the wiring layer 70 in the Z direction. The distance in the Z direction between the first resistive portion 81 and the second resistive portion 82 is less than the distance in the Z direction between the second resistive portion 82 and the wiring layer 70. In other words, the second resistive portion 82 is arranged closer to the first resistive portion 81 than the wiring layer 70 in the Z direction.

As shown in FIG. 10, when viewed from the Y direction, the second resistive portion 82 extends along the X direction. The second resistive portion 82 includes a first end portion 82A and a second end portion 82B as both ends in the X direction. The first end portion 82A is an end portion of the second resistive portion 82 in the X direction that is close to the first resistive end portion 21 (referring to FIG. 6). The second end portion 82B is an end portion of the second resistive portion 82 in the X direction that is close to the second resistive end portion 22 (referring to FIG. 6).

As shown in FIG. 8, the plurality of second resistive portions 82 of the plurality of uneven portions 80 are arranged at the same position in the Z direction. The plurality of second resistive portions 82 are arranged in the X direction and spaced apart from each other. In one example, the plurality of first resistive portions 81 and the plurality of second resistive portions 82 are alternately arranged in the X direction in top view.

In one example, the length dimension of the second resistive portion 82 is shorter than the length dimension of the first resistive portion 81. Herein, the length dimension of the second resistive portion 82 can be defined by the X-direction dimension of the second resistive portion 82. The length dimension of the first resistive portion 81 can be defined by the X-direction dimension of the first resistive portion 81.

The thickness of the second resistive portion 82 is equal to the thickness of the first resistive portion 81. Herein, as long as the difference between the thickness of the second resistive portion 82 and the thickness of the first resistive portion 81 is, for example, within 10% of the thickness of the first resistive portion 81, it can be said that the thickness of the second resistive portion 82 is the same as the thickness of the first resistive portion 81.

As shown in FIG. 10, the connecting portion 83 is a portion that connects the first resistive portion 81 with the second resistive portion 82. When viewed from the Y direction, the connecting portion 83 extends along a direction intersecting the X direction. In one example, when viewed from the Y direction, the connecting portion 83 extends along a direction intersecting both the X direction and the Z direction. That is, when viewed from the Y direction, the connecting portion 83 extends obliquely with respect to the thickness direction (Z direction) of the substrate 30.

The connecting portion 83 includes a first connecting portion 83A and a second connecting portion 83B.

The first connecting portion 83A connects the second end portion 81B of the first resistive portion 81 with the first end portion 82A of the second resistive portion 82. That is, the first connecting portion 83A constitutes a connecting portion close to the first resistive end portion 21 in the uneven portion 80. The first connecting portion 83A extends obliquely toward the substrate 30 from the second end portion 81B of the first resistive portion 81 to the first end portion 82A of the second resistive portion 82.

The length dimension of the first connecting portion 83A is greater than the thickness of the first resistive portion 81. The length dimension of the first connecting portion 83A is greater than the thickness of the second resistive portion 82. In one example, the length dimension of the first connecting portion 83A is greater than the length dimension of the second resistive portion 82. In one example, the length dimension of the first connecting portion 83A is equal to the length dimension of the first resistive portion 81. In one example, the length dimension of the first connecting portion 83A is less than the distance between adjacent semiconductor resistive layers 20 in the X direction. In one example, the length dimension of the first connecting portion 83A is less than the width dimension of the semiconductor resistive layer 20. Herein, the length dimension of the first connecting portion 83A can be defined by the dimension in the direction in which the first connecting portion 83A extends when viewed from the Y direction. In addition, the width dimension of the semiconductor resistive layer 20 can be defined by the dimension in a direction orthogonal to the direction in which the semiconductor resistive layer 20 extends in top view.

The second connecting portion 83B connects the second end portion 82B of the second resistive portion 82 with the first end portion 81A of the first resistive portion 81 of the uneven portion 80 adjacent to said second end portion 82B in the X direction. That is, the second connecting portion 83B constitutes a connecting portion close to the second resistive end portion 22 in the uneven portion 80. The second connecting portion 83B extends obliquely toward the side opposite to the substrate 30 from the second end portion 82B of the second resistive portion 82 toward the first end portion 81A of the first resistive portion 81.

The length dimension of the second connecting portion 83B is greater than the thickness of the first resistive portion 81. The length dimension of the second connecting portion 83B is greater than the thickness of the second resistive portion 82. In one example, the length dimension of the second connecting portion 83B is greater than the length dimension of the second resistive portion 82. In one example, the length dimension of the second connecting portion 83B is equal to the length dimension of the first resistive portion 81. In one example, the length dimension of the second connecting portion 83B is less than the distance between adjacent semiconductor resistive layers 20 in the Y direction. In one example, the length dimension of the second connecting portion 83B is less than the width dimension of the semiconductor resistive layer 20. Herein, the length dimension of the second connecting portion 83B can be defined by the dimension in the direction in which the second connecting portion 83B extends when viewed from the Y direction.

In addition, the distance in the Z direction between the first resistive portion 81 and the second resistive portion 82 is greater than the thickness of the first resistive portion 81. The distance in the Z direction between the first resistive portion 81 and the second resistive portion 82 is greater than the thickness of the second resistive portion 82. The distance in the Z direction between the first resistive portion 81 and the second resistive portion 82 is greater than the length dimension of the second resistive portion 82.

### [Method for Manufacturing the First Chip]

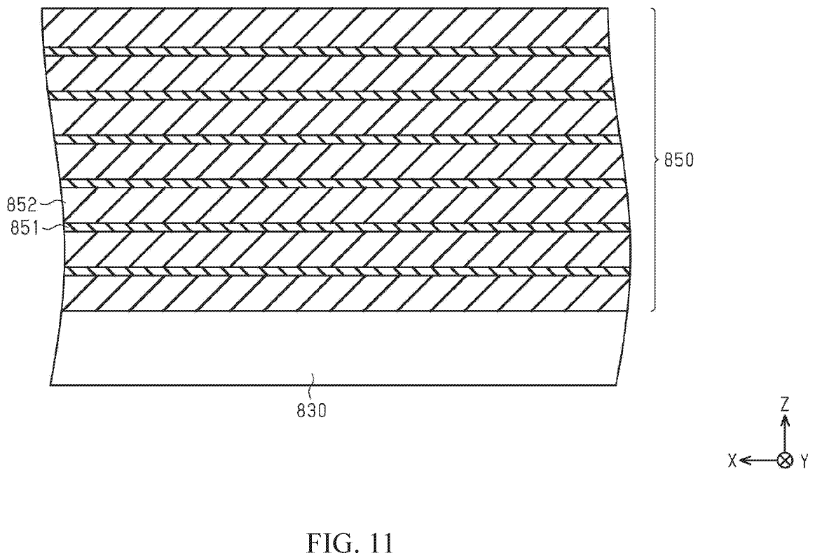

An example of a method for manufacturing the first chip 14 will be described with reference to FIGS. 11 to 20. FIGS. 11 to 20 show cross-sectional structures of components of the first chip 14 illustrating the manufacturing process of the first chip 14.

The method for manufacturing the first chip 14 mainly includes the following steps: preparing the substrate 830; forming the substrate-side insulating layer 850 on the substrate 830; forming the first surface-side insulating layer 861; forming the wiring layer 70 and the wiring layer 23; forming the second surface-side insulating layer 862; forming the connecting wiring 71 and the connecting wiring for resistive layer 72; forming the groove 864 in the second surface-side insulating layer 862; forming the semiconductor resistive layer 20; forming the third surface-side insulating layer 863; forming the connecting wiring for terminal 73; forming the terminals P1 to P5; forming the passivation film 843; and performing singulation.

As shown in FIG. 11, in the step of preparing the substrate 830, for example, the substrate 830, which is a Si substrate, is prepared. The substrate 830 is a component constituting the substrate 30, and is, for example, a semiconductor wafer. Herein, the substrate 830 is configured to include a plurality of substrates 30.

Next, the step of forming the substrate-side insulating layer 850 on the substrate 830 is performed. In this step, the substrate-side insulating layer 850 is formed on the substrate 830 using, for example, chemical vapor deposition (CVD). More specifically, the etching stop films 851 and the interlayer insulating films 852 are formed in an alternately stacked manner using, for example, CVD. The substrate-side insulating layer 850 is an insulating layer constituting the substrate-side insulating layer 50. The etching stop film 851 is an insulating film constituting the etching stop film 51, and the interlayer insulating film 852 is an insulating film constituting the interlayer insulating film 52.

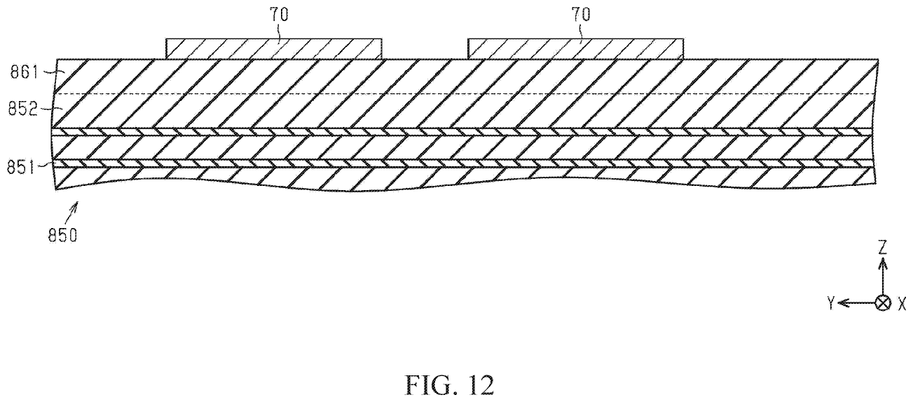

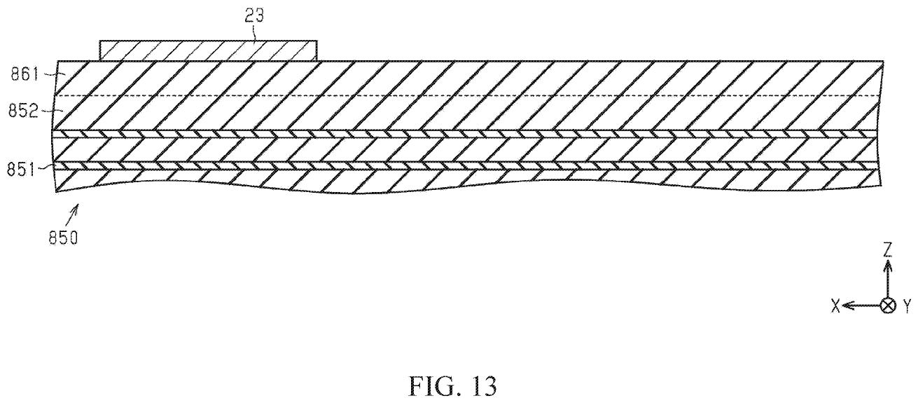

FIG. 12 shows the step of forming the first surface-side insulating layer 861 and the step of forming the wiring layer 70 among the steps of forming the wiring layer 70 and the wiring layer 23. FIG. 13 shows the step of forming the wiring layer 23 among the steps of forming the wiring layer 70 and the wiring layer 23.

As shown in FIG. 12, in the step of forming the first surface-side insulating layer 861, the first surface-side insulating layer 861 is formed on the substrate-side insulating layer 850 by, for example, CVD. The first surface-side insulating layer 861 is formed of a material containing SiO₂, for example. The first surface-side insulating layer 861 is an insulating layer constituting a portion of the surface-side insulating layer 60 between the substrate-side insulating layer 50 and the wiring layer 70. In this way, the step of forming the first surface-side insulating layer 861 is a step that forms a portion of the surface-side insulating layer 860.

In FIG. 12, the interface between the first surface-side insulating layer 861 and the substrate-side insulating layer 50 (interlayer insulating film 852) in contact with the first surface-side insulating layer 861 is indicated by a double-dot chain line. However, since the first surface-side insulating layer 861 and the interlayer insulating film 852 are actually made of the same material, the interface between the first surface-side insulating layer 861 and the interlayer insulating film 852 may not be visually recognized.

Next, as shown in FIGS. 12 and 13, in the step of forming the wiring layer 70 and the wiring layer 23, a metal film (not shown) that serves as a material film of the wiring layer 70 and the wiring layer 23 is formed on the first surface-side insulating layer 861 by a sputtering method, for example. The metal film may be appropriately selected from one or more of Ti, TiN, Ta, TaN, Au, Ag, Cu, Al, and W, for example. Next, the wiring layer 70 and the wiring layer 23 are formed by patterning the metal film using, for example, photolithography and etching. That is, the wiring layer 70 and the wiring layer 23 are formed simultaneously by patterning the metal film. In addition, although not shown in the figure, the wiring layers 24 to 27 (referring to FIG. 3) are also formed simultaneously with the wiring layer 23 by patterning the metal film.

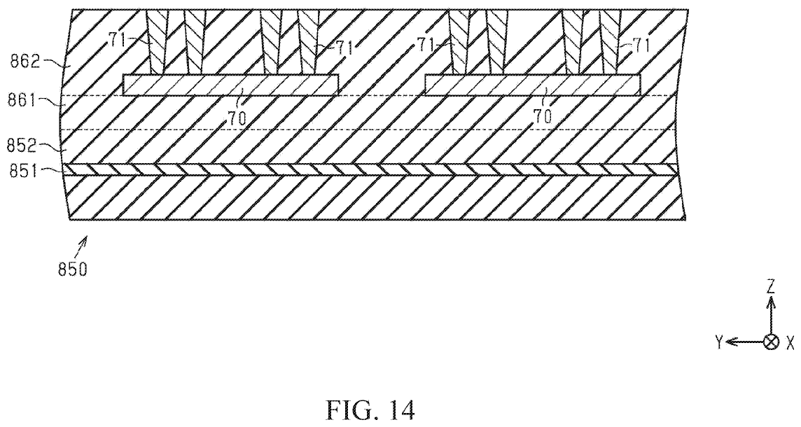

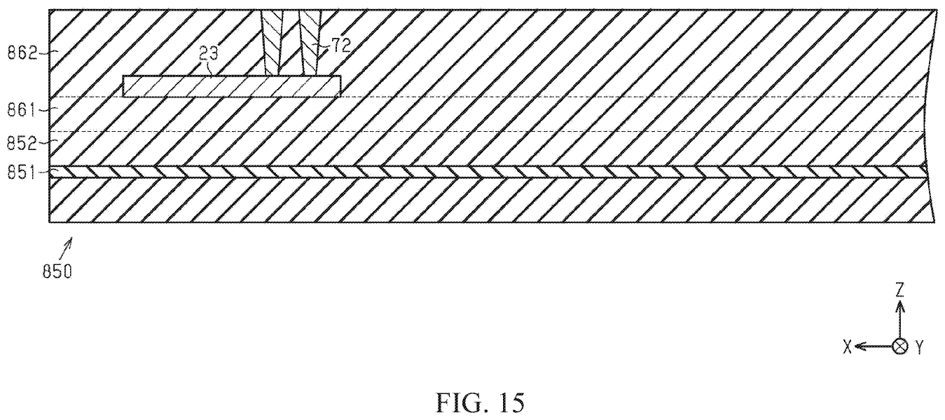

FIG. 14 shows the step of forming the connecting wiring 71 among the steps of forming the connecting wiring 71 and the connecting wiring for resistive layer 72. FIG. 15 shows the step of forming the connecting wiring for resistive layer 72 among the steps of forming the connecting wiring 71 and the connecting wiring for resistive layer 72.

As shown in FIGS. 14 and 15, in the step of forming the second surface-side insulating layer 862, the second surface-side insulating layer 862 is formed on the first surface-side insulating layer 861 by, for example, CVD so as to cover the wiring layer 70 and the wiring layers 23 to 27. The second surface-side insulating layer 862 is an insulating layer constituting a portion of the surface-side insulating layer 860. The second surface-side insulating layer 862 is formed of a material containing SiO₂, for example. In this way, the step of forming the second surface-side insulating layer 862 is a step of forming a portion of the surface-side insulating layer 860.

Next, in the step of forming the connecting wiring 71 and the connecting wiring for resistive layer 72, first, an opening for via is formed by etching, for example. The opening for via shown in FIG. 14 penetrates the second surface-side insulating layer 862 in the Z direction and exposes the wiring layer 70. The opening for via shown in FIG. 15 penetrates the second surface-side insulating layer 862 in the Z direction and exposes the wiring layer 23. Next, the metal material is filled into the opening for via shown in FIGS. 14 and 15 by, for example, the sputtering method. For example, the metal material may be appropriately selected from one or more of Ti, TIN, Ta, TaN, Au, Ag, Cu, Al, and W. As a result, the connecting wiring 71 and the connecting wiring for resistive layer 72 are formed. Both the connecting wiring 71 and the connecting wiring for resistive layer 72 are exposed from the second surface-side insulating layer 862 in the Z direction.

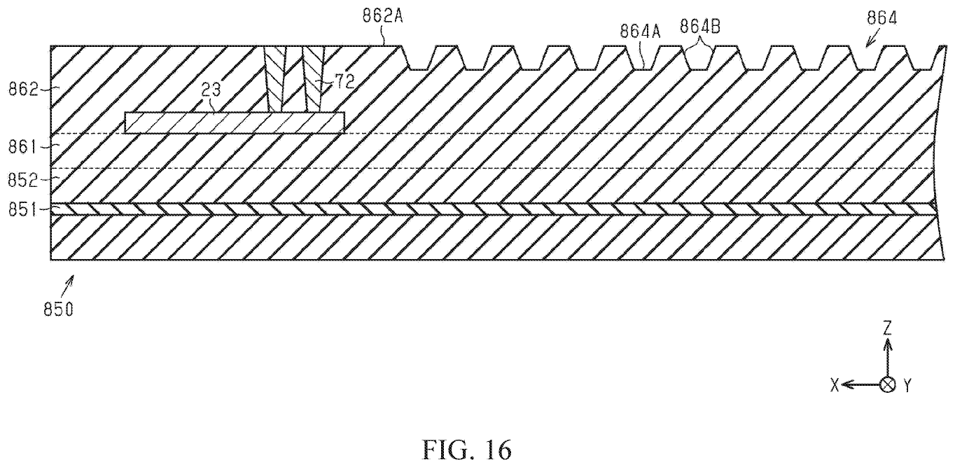

FIG. 16 shows the step of forming grooves 864 in the second surface-side insulating layer 862.

In the step of forming the groove 864 in the second surface-side insulating layer 862, the groove 864 is formed to be recessed from the surface 862A of the second surface-side insulating layer 862 by, for example, etching. As the etching, dry etching is used, for example. As dry etching, reactive ion etching (RIE) is used, for example.

Plural grooves 864 are formed. The plural grooves 864 are formed to be spaced apart from each other in the X direction. Each groove 864 extends along the X direction. When viewed from the Y direction, each groove 864 is formed in a trapezoidal shape that becomes tapered toward the substrate-side insulating layer 850. In one example, the plural grooves 864 have the same shape as each other.

Each groove 864 includes a bottom surface 864A and a pair of inclined surfaces 864B extending in a direction intersecting both the Z direction and the X direction from the bottom surface 864A toward the surface 862A of the second surface-side insulating layer 862. The bottom surface 864A is formed, for example, by a plane orthogonal to the Z direction. Each inclined surface 864B connects the bottom surface 864A with the surface 862A.

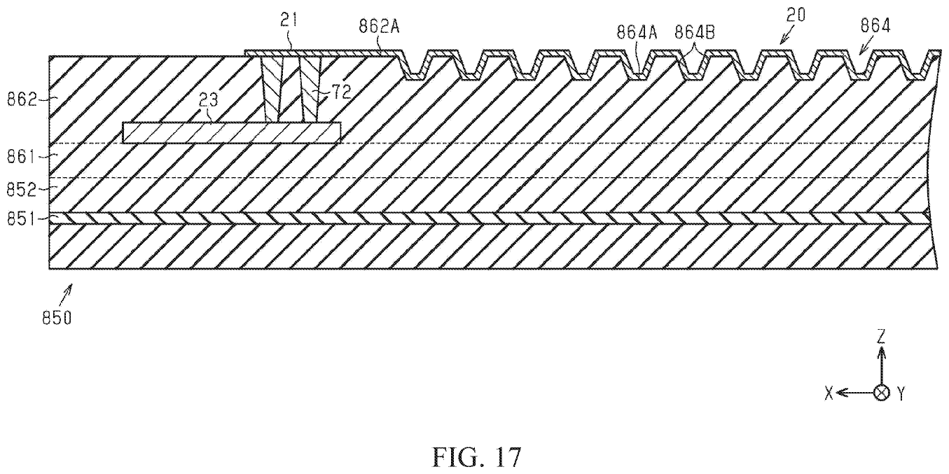

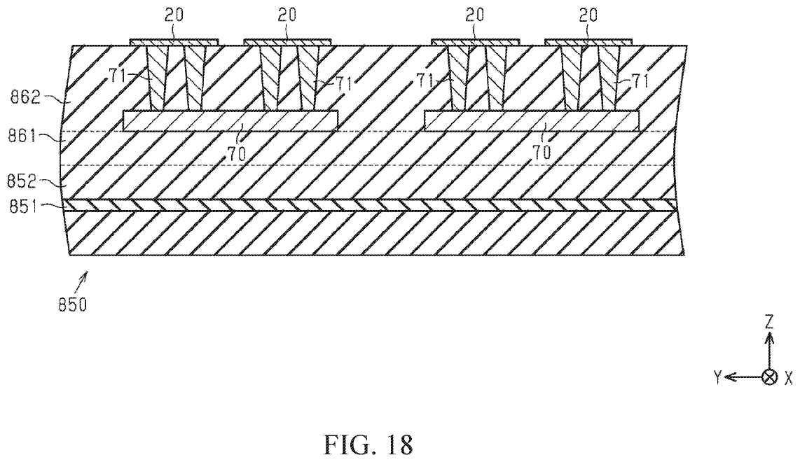

FIGS. 17 and 18 illustrate the step of forming the semiconductor resistive layer 20.

In the step of forming the semiconductor resistive layer 20, a resistance material film that is a material film of the semiconductor resistive layer 20 is formed on each groove 864 and on the surface 862A of the second surface-side insulating layer 862. The resistive material film is formed of a material containing CrSi, for example. The resistive material film is formed over each groove 864 and the entire surface 862A of the second surface-side insulating layer 862. More specifically, the resistive material film is formed in contact with the bottom surface 864A and the pair of inclined surfaces 864B of each groove 864 and in contact with the surface 862A. Next, the semiconductor resistive layer 20 is formed by patterning the resistance material film using photolithography and etching, for example. Thereby, the semiconductor resistive layer 20 is formed along the surface 862A of the second surface-side insulating layer 862 and the grooves 864. In addition, the upper end of the connecting wiring 71 and the upper end of the connecting wiring for resistive layer 72 are each connected to the semiconductor resistive layer 20.

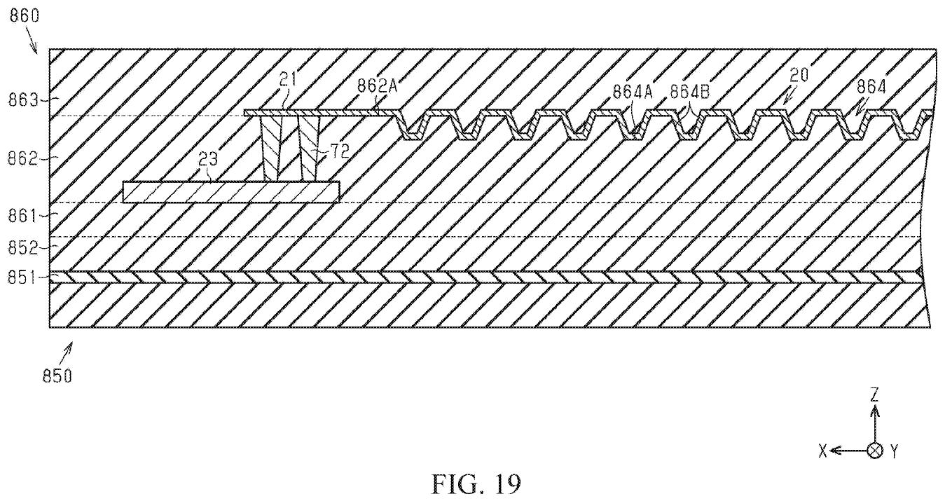

FIG. 19 shows the steps of forming the third surface-side insulating layer 863.

In the step of forming the third surface-side insulating layer 863, the third surface-side insulating layer 863 is formed on the second surface-side insulating layer 862 so as to cover the semiconductor resistive layer 20 and fill the grooves 864 by, for example, CVD. The third surface-side insulating layer 863 is an insulating layer constituting a portion of the surface-side insulating layer 860. The third surface-side insulating layer 863 is formed of a material containing SiO₂, for example. The surface-side insulating layer 860 is formed through the above steps.

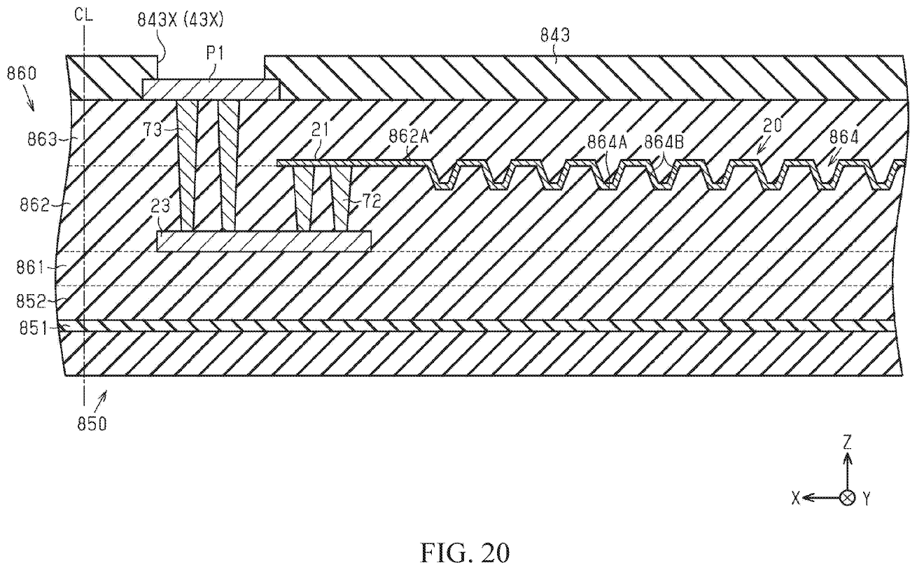

FIG. 20 shows the step of forming the connecting wiring for terminal 73, the step of forming the terminal P1, the step of forming the passivation film 843, and the step of performing singulation. In addition, although not shown in the figure, the terminals P2 to P5 are formed simultaneously with the terminal P1.

In the step of forming the connecting wiring for terminal 73, first, an opening for via is formed by etching, for example. The opening for via shown in FIG. 20 penetrates both the third surface-side insulating layer 863 and the second surface-side insulating layer 862 in the Z direction, and exposes the wiring layer 23. Next, the metal material is filled into the opening for via by, for example, sputtering. For example, the metal material may be appropriately selected from one or more of Ti, TiN, Ta, TaN, Au, Ag, Cu, Al, and W. Thus, the connecting wiring for terminal 73 is formed. The connecting wiring for terminal 73 is exposed from the third surface-side insulating layer 863 in the Z direction.

Next, in the step of forming the terminal P1, a metal film as a material film of the terminal P1 is formed on the third surface-side insulating layer 863 by, for example, sputtering. The metal film is connected with the connecting wiring for terminal 73. For example, the metal film may be appropriately selected from one or more of Ti, TiN, Ta, TaN, Au, Ag, Cu, Al, and W. Next, the metal film is patterned using photolithography and etching to form the terminal P1. In addition, although not shown in the figure, the terminals P2 to P5 are also formed in the same manner. In this way, the terminals P1 to P5 are connected to the connecting wirings for terminal 73 respectively.

Next, in the step of forming the passivation film 843, first, for example, a passivation material film as a material film of the passivation film 843 is formed on the third surface-side insulating layer 863 and on the terminals P1 to P5. Next, a portion of the portion of the passivation material film covering the terminals P1 to P5 is removed, for example, by etching. That is, portions of the terminals P1 to P5 are exposed from the passivation material film. It can also be said that the passivation film 843 is formed with the openings 843X exposing the terminals P1 to P5. Thereby, the passivation film 843 is formed from the passivation material film. The passivation film 843 is a film constituting the passivation film 43 and is formed of a material containing SiN, for example. In addition, in FIG. 20, the opening 843X exposing the terminal P1 is shown. The opening 843X corresponds to the opening 43X.

Next, in the step of performing singulation, the passivation film 843, the surface-side insulating layer 860, the substrate-side insulating layer 850, and the substrate 830 are cut along the cutting line CL in FIG. 20 using, for example, a dicing knife. Thereby, the passivation film 43, the surface-side insulating layer 60, the substrate-side insulating layer 50, and the substrate 30 are formed. The first chip 14 is manufactured through the above steps.

### [Functions]

The function of the semiconductor module 10 according to the first embodiment will be described.

In the first chip 14, the resistance value is mainly determined based on the total length of the plurality of semiconductor resistive layers 20. In the first embodiment, since the semiconductor resistive layer 20 has the uneven portions 80, the total length of the plurality of semiconductor resistive layers 20 in top view can be shortened compared to a configuration in which the semiconductor resistive layer 20 does not have the uneven portions 80. In one example, the X-direction length of each semiconductor resistive layer 20 can be shortened. Thereby, the size of the first chip 14 in the X direction can be minimized. In addition, in another example, the number of the plurality of semiconductor resistive layers 20 can be reduced. Thereby, the size of the first chip 14 in the Y direction can be minimized.

### [Effects]

According to the semiconductor module 10 of the first embodiment, the following effects are obtained.
(1-1) The first chip 14 as a semiconductor device includes a substrate 30; an element insulating layer 40 provided on the substrate 30; and a semiconductor resistive layer 20 provided in the element insulating layer 40. The semiconductor resistive layer 20 extends along a first direction orthogonal to the thickness direction (Z direction) of the substrate 30, i.e. the X direction, and has an uneven portion 80 in the Z direction.

According to this configuration, since the semiconductor resistive layer 20 has the uneven portion 80, the X-direction length of the semiconductor resistive layer 20 in top view can be shortened. Therefore, the first chip 14 can be miniaturized in the X direction
(1-2) Plural uneven portions 80 are arranged in the X direction and spaced apart from each other.

According to this configuration, the X-direction length of the semiconductor resistive layer 20 in top view can be further shortened. Therefore, the first chip 14 can be further miniaturized in the X direction.
(1-3) The uneven portion 80 includes a first resistive portion 81 extending along the X direction; a second resistive portion 82 disposed at a position shifted from the first resistive portion 81 in the X direction and closer to the substrate 30 than the first resistive portion 81, and extending along the X direction; and a connecting portion 83 extending along a direction intersecting the X direction and connecting an end of the first resistive portion 81 along the X direction to an end of the second resistive portion 82 along the X direction. The length dimension of the connecting portion 83 is greater than the thickness of the first resistive portion 81.

According to this configuration, since the length dimension of the connecting portion 83 is greater than the thickness of the first resistive portion 81, the X-direction length of the semiconductor resistive layer 20 in top view can be shortened. Therefore, the first chip 14 can be miniaturized in the X direction.
(1-4) The length dimension of the connecting portion 83 is greater than the length dimension of the second resistive portion 82.

According to this configuration, since the length dimension of the connecting portion 83 is greater than the length dimension of the second resistive portion 82, the X-direction length of the semiconductor resistive layer 20 in top view can be shortened. Therefore, the first chip 14 can be miniaturized in the X direction.
(1-5) When viewed from the Y direction, the connecting portion 83 extends obliquely with respect to the Z direction.

According to this configuration, when the semiconductor resistive layer 20 is formed by sputtering, for example, it is easier to form the connecting portion 83 extending obliquely with respect to the Z direction, compared with a configuration in which the connecting portion 83 extends along the Z direction.
(1-6) The element insulating layer 40 includes a substrate-side insulating layer 50 provided on the substrate 30; and a surface-side insulating layer 60 laminated on the substrate-side insulating layer 50. The substrate-side insulating layer 50 has a structure in which a plurality of etching stop films 51 and a plurality of interlayer insulating films 52 that relieve the stress of the etching stop films 51 are alternately laminated one by one. The semiconductor resistive layer 20 is embedded in the surface-side insulating layer 60.

According to this configuration, by interposing the substrate-side insulating layer 50 between the semiconductor resistive layer 20 embedded in the surface-side insulating layer 60 and the substrate 30, the distance in the Z-direction between the semiconductor resistive layer 20 and the substrate 30 can be increased. Therefore, the insulation withstand voltage of the first chip 14 can be increased.

In addition, since the substrate-side insulating layer 50 has a structure in which a plurality of etching stop films 51 and a plurality of interlayer insulating films 52 that relieve the stress of the etching stop films 51 are alternately laminated one by one, even if the thickness of the substrate-side insulating layer 50 is increased, the amount of warpage of the first chip 14 can be suppressed from increasing.

### Second Embodiment

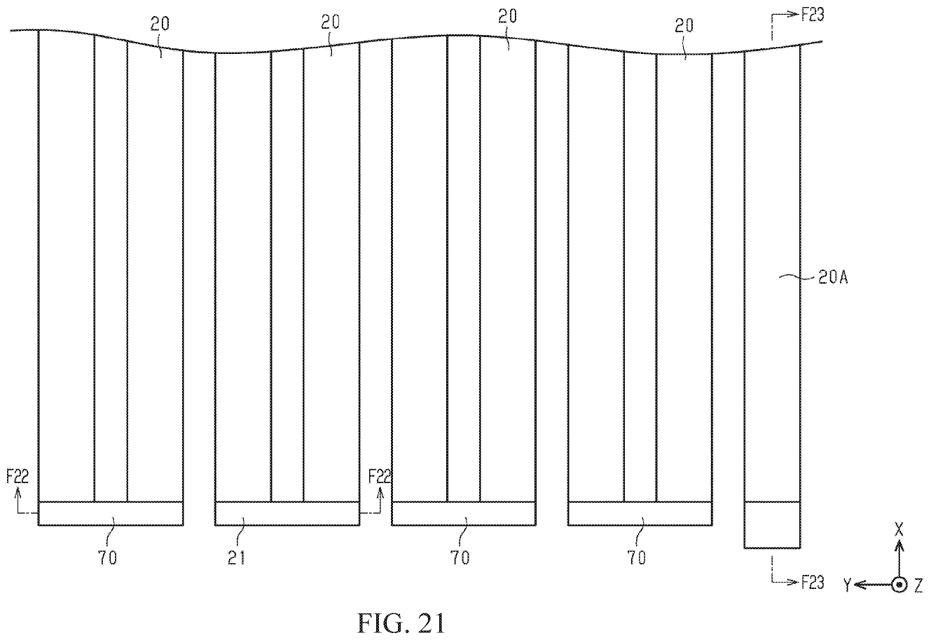

The semiconductor module 10 according to the second embodiment will be described with reference to FIGS. 21 to 23. The semiconductor module 10 of the second embodiment is different from the semiconductor module 10 of the first embodiment in the positional relationship between the semiconductor resistance layer 20 and the wiring layer 70 and the wiring layer 23. In the following description, differences from the first embodiment will be described in detail. Components that are common to the first embodiment will be denoted by the same reference numerals and their description will be omitted.

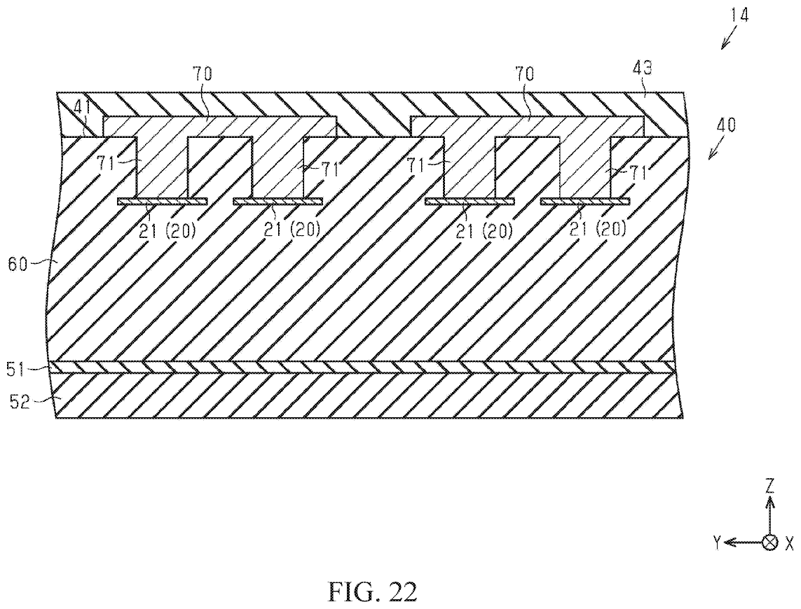

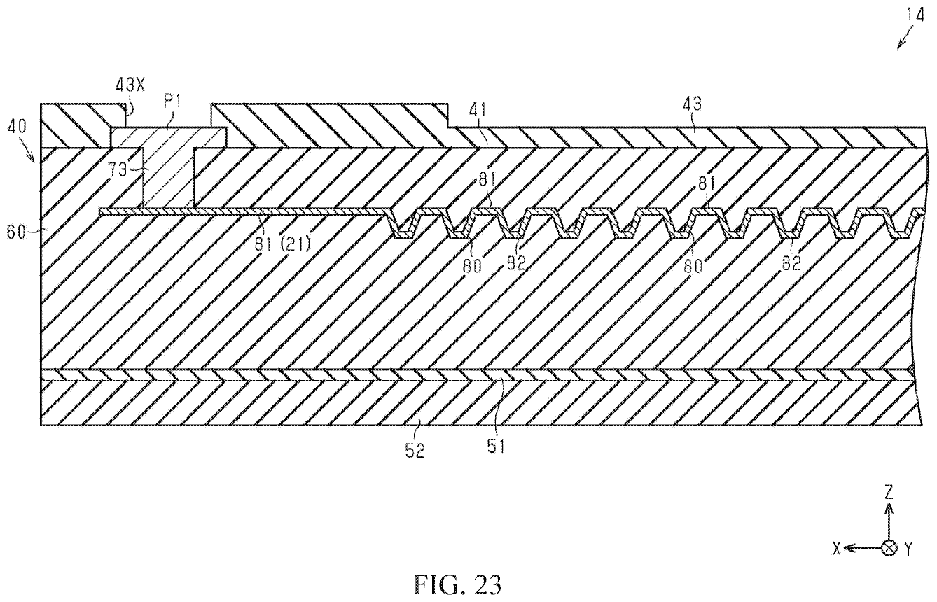

FIG. 21 shows the planar structure of the first resistive end portions 21 of the plurality of semiconductor resistive layers 20 and their surroundings. FIG. 22 is a cross-sectional structure taken along line F22-F22 in FIG. 21, and shows a connection structure between the semiconductor resistive layers 20. FIG. 23 is a cross-sectional structure taken along line F23-F23 in FIG. 21 and shows a connection structure between one semiconductor resistive layer 20 and the terminal P1.

As shown in FIGS. 21 and 22, the wiring layer 70 is arranged on the side opposite to the substrate 30 (referring to FIG. 5) with respect to the semiconductor resistive layer 20 in the Z direction. The wiring layer 70 is separated from the semiconductor resistive layer 20 in the Z direction. Therefore, a portion of the surface-side insulating layer 60 is interposed between the wiring layer 70 and the semiconductor resistive layer 20 in the Z direction. That is, it can be said that a portion of the element insulating layer 40 is interposed between the wiring layer 70 and the semiconductor resistive layer 20 in the Z direction. In the second embodiment, the wiring layer 70 is arranged on the element insulating layer 40. In one example, the wiring layer 70 is in contact with the element front surface 41 of the element insulating layer 40. Furthermore, the wiring layer 70 is covered with the passivation film 43.

The connecting wiring 71 is arranged between the wiring layer 70 and the first resistive end portion 21 of the semiconductor resistive layer 20 in the Z direction. It can be said that the connecting wiring 71 is arranged on the side opposite to the substrate 30 with respect to the semiconductor resistive layer 20 in the Z direction. In the second embodiment, the connecting wiring 71 is formed of the same material as the wiring layer 70. In one example, the connecting wiring 71 is integrally formed with the wiring layer 70.

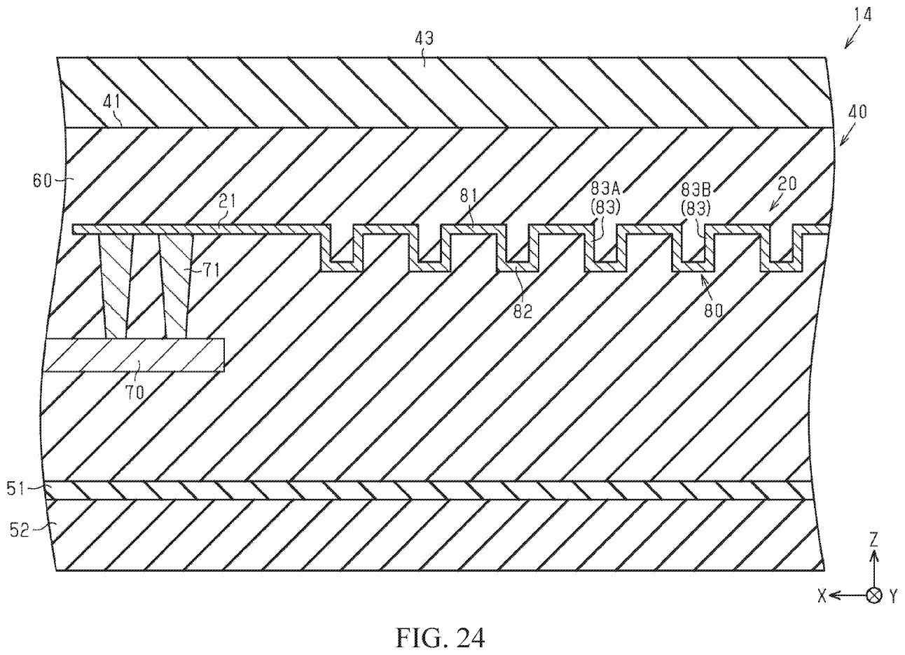

As shown in FIG. 24, in the second embodiment, the X-direction length of the semiconductor resistive layer 20A is longer than the X-direction length of the other semiconductor resistive layers 20. Thereby, the first resistive end portion 21 of the semiconductor resistive layer 20A is formed at a position shifted along the X direction from the first resistive end portions 21 of the other semiconductor resistive layers 20. The first resistive end portion 21 of the semiconductor resistive layer 20A is formed at a position overlapping the terminal P1 in top view.

The connecting wiring for terminal 73 is arranged in the Z direction between the first resistive end portion 21 of the semiconductor resistive layer 20A and the terminal P1. It can be said that the connecting wiring for terminal 73 is arranged on the side opposite to the substrate 30 (referring to FIG. 5) with respect to the semiconductor resistive layer 20 in the Z direction. In the second embodiment, the connecting wiring for terminal 73 is formed of the same material as the terminal P1. In one example, the connecting wiring for terminal 73 is integrally formed with the terminal P1. Thus, in the second embodiment, the wiring layer 23 is omitted (referring to FIG. 6).

In addition, although not shown in the figure, the wiring layer 24 (referring to FIG. 3) may be omitted from the first chip 14 like the wiring layer 23. In this case, the semiconductor resistive layer 20B has the same configuration as the semiconductor resistive layer 20A.

In addition, the wiring layers 25 to 27 may be formed on the element front surface 41 of the element insulating layer 40, for example. In this case, the first resistive end portions 21 of the semiconductor resistive layers 20 that overlap the wiring layers 25 to 27 in top view are connected to the wiring layers 25 to 27 by the connecting wirings for terminal (not shown). The structure of the connecting wiring for terminal is the same as the connecting wiring for terminal 73 shown in FIG. 24. In addition, the wiring layers 23 and 24 may be configured similarly to the wiring layers 25 to 27.

### [Effects]

According to the semiconductor module 10 of the second embodiment, in addition to the effects of the semiconductor module 10 of the first embodiment, the following effects are further obtained.
(2-1) The first chip 14 further includes the wiring layer 70 electrically connected to the semiconductor resistive layer 20. The wiring layer 70 is arranged on the side opposite to the substrate 30 with respect to the semiconductor resistive layer 20 in the Z direction. According to this configuration, the distance between the wiring layer 70 and the substrate 30 in the Z direction can be increased. Therefore, the insulation withstand voltage of the first chip 14 can be improved.

### Modified Examples

Each of the above-described embodiments can be modified and implemented as follows. In addition, each of the above-described embodiments and the following modified examples can be implemented in combination with each other within the scope of no technical contradiction.
In each embodiment, the structure of the semiconductor resistive layer 20 can be modified arbitrarily.

In one example, the length dimension of the second resistive portion 82 may be equal to the length dimension of the first resistive portion 81. Herein, as long as the difference between the length dimension of the second resistive portion 82 and the length dimension of the first resistive portion 81 is within 10%, it can be said that the length dimension of the second resistive portion 82 is equal to the length dimension of the first resistive portion 81. In addition, the length dimension of the second resistive portion 82 may be greater than the length dimension of the first resistive portion 81.

In one example, the length dimension of the first connecting portion 83A may be less than the length dimension of the first resistive portion 81. In one example, the length dimension of the first connecting portion 83A may be greater than the length dimension of the first resistive portion 81. In one example, the length dimension of the first connecting portion 83A may be equal to the length dimension of the second resistive portion 82. Herein, as long as the difference between the length dimension of the first connecting portion 83A and the length dimension of the second resistive portion 82 is, for example, within 10% of the length dimension of the second resistive portion 82, it can be said that the length dimension of the first connecting portion 83A is the same as the length dimension of the second resistive portion 82. In one example, the length dimension of the first connecting portion 83A may be less than the length dimension of the second resistive portion 82.

In one example, the length dimension of the first connecting portion 83A may be equal to the distance between adjacent semiconductor resistive layers 20 in the Y direction. Herein, as long as the difference between the length dimension of the first connecting portion 83A and the distance between the adjacent semiconductor resistive layers 20 in the Y direction is, for example, within 10% of the length dimension of the first connecting portion 83A, the length dimension of the first connecting portion 83A can be said to be equal to the distance between adjacent semiconductor resistive layers 20 in the Y direction. In one example, the length dimension of the first connecting portion 83A may be greater than the distance between adjacent semiconductor resistive layers 20 in the Y direction.

In one example, the length dimension of the second connecting portion 83B may be less than the length dimension of the first resistive portion 81. In one example, the length dimension of the second connecting portion 83B may be greater than the length dimension of the first resistive portion 81. In one example, the length dimension of the second connecting portion 83B may be equal to the length dimension of the second resistive portion 82. Herein, as long as the difference between the length dimension of the second connecting portion 83B and the length dimension of the second resistive portion 82 is, for example, within 10% of the length dimension of the second resistive portion 82, it can be said that the length dimension of the second connecting portion 83B is equal to the length dimension of the second resistive portion 82. In one example, the length dimension of the second connecting portion 83B may be less than the length dimension of the second resistive portion 82.

In one example, the length dimension of the second connecting portion 83B may be equal to the distance between adjacent semiconductor resistive layers 20 in the Y direction. Herein, as long as the difference between the length dimension of the second connecting portion 83B and the distance between the adjacent semiconductor resistive layers 20 in the Y direction is, for example, within 10% of the length dimension of the second connecting portion 83B, it can be said that the length dimension of the second connecting portion 83B is equal to the distance between adjacent semiconductor resistive layers 20 in the Y direction. In one example, the length dimension of the second connecting portion 83B may be greater than the distance between adjacent semiconductor resistive layers 20 in the Y direction.
In the first embodiment, the wiring layer 70 may be formed on the substrate-side insulating layer 50 at a position in contact with the substrate-side insulating layer 50. In this case, in the method for manufacturing the first chip 14, the step of forming the first surface-side insulating layer 861 is omitted. In addition, the wiring layers 23 to 27 can also be formed on the substrate-side insulating layer 50 at positions in contact with the substrate-side insulating layer 50.
In the second embodiment, the wiring layer 70 may be arranged between the semiconductor resistive layer 20 and the element front surface 41 of the element insulating layer 40 in the Z direction. In this case, the wiring layer 70 is embedded in the element insulating layer 40.
In the second embodiment, the wiring layer 23 may be arranged between the semiconductor resistive layer 20 and the element front surface 41 of the element insulating layer 40 in the Z direction. In this case, the wiring layer 23 is embedded in the element insulating layer 40.
In each embodiment, the shape of the semiconductor resistive layer 20 when viewed from the X direction can be arbitrarily changed. For example, for the shape of the uneven portion 80 of the semiconductor resistive layer 20 when viewed from the X direction, the first to third examples shown in FIGS. 24 to 26 can be exemplified.

As shown in FIG. 24, in the first example, the uneven portion 80 is formed in a rectangular shape when viewed from the X direction. Both the first connecting portion 83A and the second connecting portion 83B of the uneven portion 80 extend along the Z direction. In the example shown in FIG. 24, the length dimension of the first resistive portion 81 is equal to the length dimension of the second resistive portion 82. In addition, the length dimension of the first resistive portion 81 and the length dimension of the second resistive portion 82 can each be changed arbitrarily. The length dimension of the first resistive portion 81 may be greater than the length dimension of the second resistive portion 82. The length dimension of the first resistive portion 81 may be less than the length dimension of the second resistive portion 82.

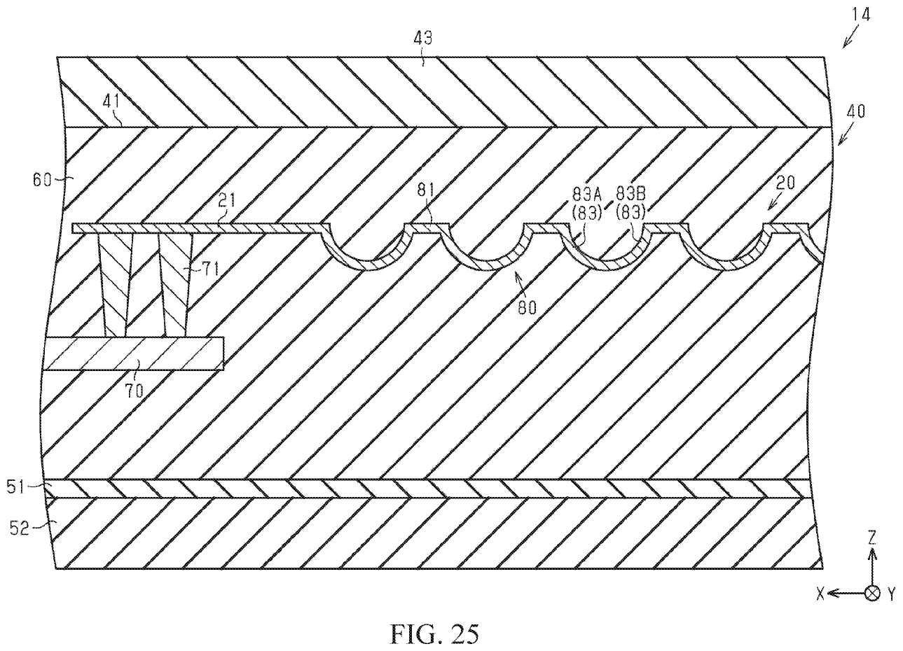

As shown in FIG. 25, in the second example, the uneven portion 80 is formed in a curved shape when viewed from the X direction. More specifically, both the first connecting portion 83A and the second connecting portion 83B of the uneven portion 80 are formed in a curved shape when viewed from the X direction. In addition, in the second example, the second resistive portion 82 may be omitted from the uneven portion 80. That is, the uneven portion 80 may be formed in a semicircular shape, an elliptical shape, or an arc shape when viewed from the X direction.

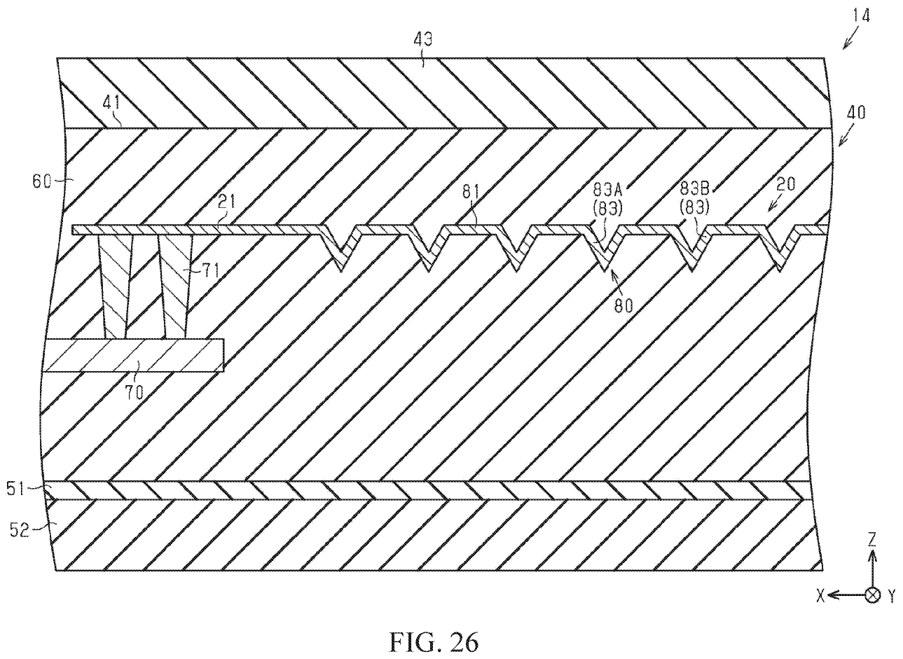

As shown in FIG. 26, in the third example, the uneven portion 80 is formed in a V-shape when viewed from the X direction. In this case, the second resistive portion 82 is omitted from the uneven portion 80. That is, the first connecting portion 83A is connected to the second connecting portion 83B.
In each embodiment, the position of the first resistive end portion 21 of the semiconductor resistive layer 20 in the Z direction can be changed arbitrarily. In one example, the first resistive end portion 21 may be located at the same position as the second resistive portion 82 in the Z direction. In addition, in one example, the first resistive end portion 21 may be disposed between the first resistive portion 81 and the second resistive portion 82 in the Z direction.
In each embodiment, the position of the second resistive end portion 22 of the semiconductor resistive layer 20 in the Z direction can be arbitrarily changed. In one example, the second resistive end portion 22 may be located at the same position as the second resistive portion 82 in the Z direction. In one example, the second resistive end portion 22 may be disposed between the first resistive portion 81 and the second resistive portion 82 in the Z direction.
In each embodiment, the position of the second resistive portion 82 in the Z direction can be changed arbitrarily. In one example, the second resistive portion 82 may be located between the first resistive portion 81 and the wiring layer 70 in the Z direction, and may be located closer to the wiring layer 70 than the first resistive portion 81.

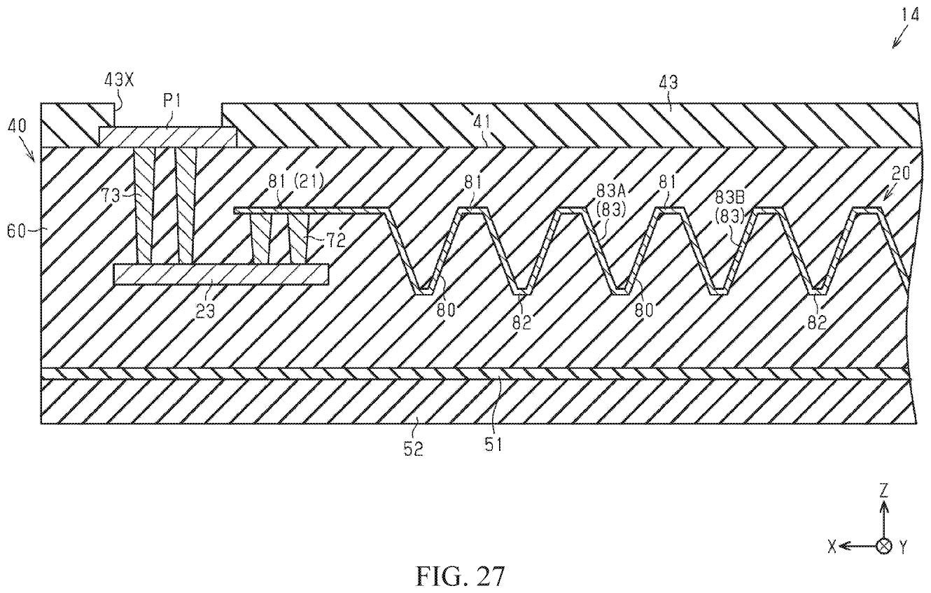

In one example, as shown in FIG. 27, the second resistive portion 82 may be disposed closer to the substrate 30 (referring to FIG. 5) than the wiring layer 70 in the Z direction. It can also be said that the second resistive portion 82 is disposed closer to the substrate-side insulating layer 50 than the wiring layer 70 in the Z direction. In this case, the length dimension of both the first connecting portion 83A and the second connecting portion 83B is greater than the length dimension of the first resistive portion 81. The length dimension of both the first connecting portion 83A and the second connecting portion 83B is greater than the width dimension of the semiconductor resistive layer 20. The length dimension of both the first connecting portion 83A and the second connecting portion 83B is greater than the distance between adjacent semiconductor resistive layers 20 in the X direction.

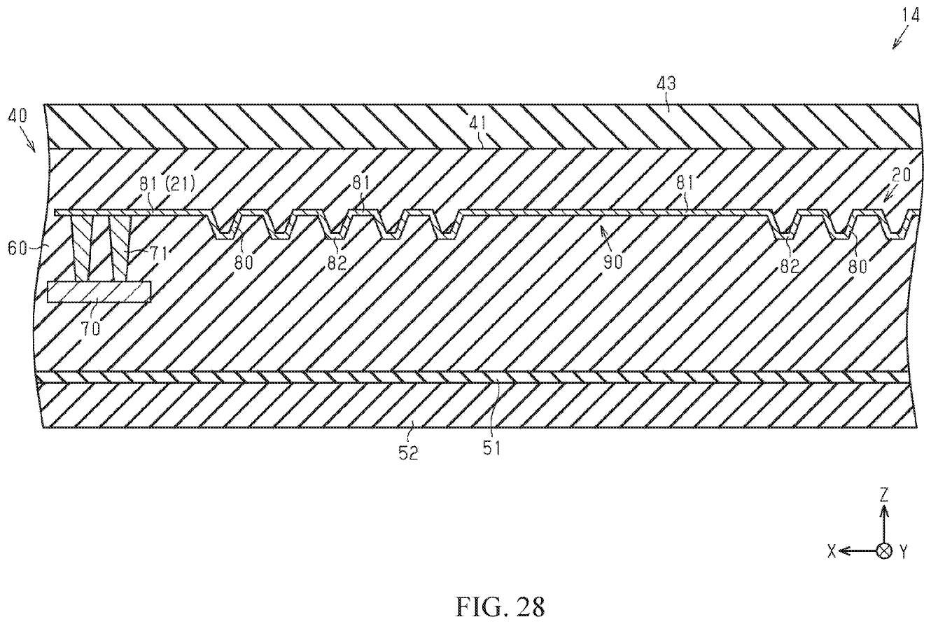

According to this configuration, the area of the semiconductor resistive layer 20 facing the substrate 30 in top view can be reduced so that the resistance value of the semiconductor resistive layer 20 becomes a preset value. Therefore, the parasitic capacitance between the semiconductor resistive layer 20 and the substrate 30 can be reduced. In addition, the length dimension of the semiconductor resistive layer 20 in the Y direction in top view can be reduced so that the resistance value of the semiconductor resistive layer 20 becomes a preset value, or the number of semiconductor resistive layers 20 arranged in the X direction can be reduced. Therefore, the chip size of the first chip 14 can be reduced.
In each embodiment, the uneven portion 80 only needs to be provided in at least a portion of the portion between the first resistive end portion 21 and the second resistive end portion 22 of the semiconductor resistive layer 20 in the Y direction. In one example, as shown in FIG. 28, the semiconductor resistive layer 20 may be formed in the flat area 90 where the uneven portion 80 is not formed. In the flat region 90, the semiconductor resistive layer 20 extends along the Y direction with the same position in the Z direction. In the example of FIG. 28, the semiconductor resistive layer 20 in the flat region 90 is located at the same position as the first resistive portion 81 in the Z direction. In addition, the semiconductor resistive layer 20 in the flat region 90 may be located at the same position as the second resistive portion 82 in the Z direction.
In each embodiment, the number of semiconductor resistive layers 20 can be changed arbitrarily. In one example, the number of semiconductor resistive layers 20 may be one. When the number of the semiconductor resistive layer 20 is one, the semiconductor resistive layer 20 may be formed into a bellows shape in top view, for example.
In each embodiment, the structure of the substrate-side insulating layer 50 can be arbitrarily changed. In one example, the substrate-side insulating layer 50 may not include the etching stop film 51 and may be formed of the interlayer insulating film 52.
In each embodiment, the passivation film 43 may be omitted from the first chip 14.
In the step of forming the groove 864 in the first surface-side insulating layer 861 in each embodiment, the shape of the groove 864 can be arbitrarily changed. In one example, a plurality of grooves 864 may be spaced apart from each other in both the X direction and the Y direction. That is, the groove 864 may also include a plurality of recesses.
In each embodiment, the number of semiconductor chips included in the semiconductor module 10 can be changed arbitrarily. In one example, the semiconductor module 10 may include a third chip in addition to the first chip 14 and the second chip 15. The third chip is electrically connected to at least one of the first chip 14 and the second chip 15 through a wire, for example.
In each embodiment, the second chip 15 may be omitted from the semiconductor module 10. In this case, the die mount 12 may be omitted from the semiconductor module 10. In addition, the semiconductor module 10 may be provided with three lead wires individually connected to P3 to P5 of the first chip 14 via the wires W3 to W5 instead of the lead 13A to 13G. In addition, the leads 13A to 13G may be omitted from the semiconductor module 10. That is, the semiconductor module 10 only needs to include the first chip 14 (semiconductor device), the frame 11 that supports the first chip 14, and the sealing resin 16 that seals the first chip 14 and the frame 11.

One or more of the various examples described in this specification may be combined within the scope of no technical contradiction.

The term “on” used in the present disclosure includes the meaning of “on” and “above” unless the context clearly indicates otherwise. Therefore, the expression “A is formed on B” means that in each of the described embodiments, A can be in contact with B and be directly arranged on B. However, as a modified example, A can be arranged above B without being in contact with B. In other words, the term “on” does not exclude the formation of other components between A and B.

The Z direction used in the present disclosure is not necessarily the vertically straight direction, nor does it need to be completely consistent with the vertically straight direction. Therefore, various structures of the present disclosure are not limited to “upper” and “lower” in the Z direction described in this specification being “upper” and “lower” in the vertically straight direction. For example, the X direction may be a vertically straight direction, or the Y direction may be a vertically straight direction.

### (Notes)

The technical ideas that can be grasped from each of the above embodiments and modifications are described below. It should be noted that, for the purpose of assisting understanding rather limiting, the corresponding reference numerals in the embodiments for the configurations described in the supplementary notes are shown in parentheses. The symbols are shown as examples to aid understanding, and the components described with each symbol should not be limited to the components indicated by the symbols.

### (Note A1)

A semiconductor device (14), comprising:
   a substrate (30);
   an element insulating layer (40), disposed on the substrate (30); and
   a semiconductor resistive layer (20), disposed within the element insulating layer (40), wherein
   the semiconductor resistive layer (20) extends along a first direction (X direction) perpendicular to a thickness direction (Z direction) of the substrate (30) and includes an uneven portion (80) along the thickness direction.

### (Note A2)

The semiconductor device of Note A1, wherein the uneven portion (80) is multiply disposed and spaced apart from each other along the first direction (X direction).

### (Note A3)

The semiconductor device of Note A2, wherein the plurality of uneven portions (80) are disposed in the same pitch along the first direction (X direction).

### (Note A4)

The semiconductor device of any one of Notes A1 to A3, wherein the uneven portion (80) includes:
   a first resistive portion (81), extending along the first direction (X direction);
   a second resistive portion (82), located at a position shifted from the first resistive portion (81) along the first direction (X direction) and closer to the substrate (30) than the first resistive portion (81), wherein the second resistive portion (82) extends along the first direction (X direction); and
   a connecting portion (83/83A), extending along a direction intersecting the first direction (X direction) and connecting an end (81B) of the first resistive portion (81) along the first direction (X direction) to an end (81A) of the second resistive portion (82) along the first direction (X direction).

### (Note A5)

The semiconductor device of Note A4, wherein a length of the second resistive portion (82) is less than a length of the first resistive portion (81).

### (Note A6)

The semiconductor device of Note A4 or A5, wherein a length of the connecting portion (83) is greater than a thickness of the first resistive portion (81).

### (Note A7)

The semiconductor device of any one of Notes A4 to A6, wherein a length of the connecting portion (83) is greater than a length of the second resistive portion (82).

### (Note A8)

The semiconductor device of any one of Notes A4 to A7, wherein
   a direction perpendicular to both the first direction (X direction) and the thickness direction (Z direction) is set as a second direction (Y direction), and
   the connecting portion (83) extends obliquely with respect to the thickness direction (Z direction) when viewed from the second direction (Y direction).

### (Note A9)

The semiconductor device of any one of Notes A1 to A8, further comprising a wiring layer (70) electrically connected to the semiconductor resistive layer (20), wherein the wiring layer (70) is disposed closer to the substrate (30) than the semiconductor resistive layer (20) along the thickness direction (Z direction).

### (Note A10)

The semiconductor device of any one of Notes A1 to A9, further comprising a wiring layer (70) electrically connected to the semiconductor resistive layer (20), wherein the wiring layer (70) is disposed at a side opposite to the substrate (30) with respect to the semiconductor resistive layer (20) along the thickness direction (Z direction).

### (Note A11)

The semiconductor device of Note 10, wherein the wiring layer (70) is disposed on the element insulating layer (40) and covered by a passivation film (43) covering the element insulating layer (40).

### (Note A12)

The semiconductor device of any one of Notes A1 to A11, further comprising:
   a wiring layer (70), electrically connected to the semiconductor resistive layer (20); and
   a connecting wiring (71), connecting the semiconductor resistive layer (20) to the wiring layer (70), wherein
   the semiconductor resistive layer (20)
      is disposed at a position different from a position of the uneven portion (80) along the first direction (X direction), and
      includes a resistive end portion (21) to which the connection wiring (71) is connected.

### (Note A13)

The semiconductor device of any one of Notes A1 to A12, wherein
   the semiconductor resistive layer (20) is multiply disposed,
   a direction perpendicular to both the first direction (X direction) and the thickness direction (Z direction) is set as a second direction (Y direction), and
   the plurality of semiconductor resistive layers (20) are spaced apart along the second direction (Y direction).

### (Note A14)

The semiconductor device of any one of Notes A1 to A13, wherein the element insulating layer (40) includes:
   a substrate-side insulating layer (50), disposed on the substrate (30); and
   a front-side insulating layer (60), laminated on the substrate-side insulating layer (50), wherein
   the substrate-side insulating layer (50) is formed by a plurality of first insulating films (51) and a plurality of second insulating films (52) alternately stacked with each other, the second insulating films (52) are configured for relieving stress of the plurality of first insulating films (51), and
   the semiconductor resistive layer (20) is embedded in the surface-side insulating layer (60).

### (Note A15)

A semiconductor module (10), comprising:
   the semiconductor device of (14) of any one of Notes A1 to A14;
   a support member (11), supporting the semiconductor device (14); and
   a sealing resin (16), sealing the semiconductor device (14) and the support member (11).

### (Note B1)

A method for manufacturing a semiconductor device (14), including the following steps:
   preparing a substrate (830);
   forming a substrate-side insulating layer (850) on the substrate (830);
   forming a portion of a surface-side insulating layer (861, 862) on the substrate-side insulating layer (850);
   forming a groove (864) on a surface (862A) of the surface-side insulating layer (862);
   forming a semiconductor resistive layer (20) along the surface (862A) of the surface-side insulating layer (862) and the groove (864); and
   forming a surface-side insulating layer (863) on the surface-side insulating layer (862) in a manner to cover the semiconductor resistive layer (20) and fill the groove (864).

The above description is merely illustrative. In addition to the components and methods (manufacturing processes) listed for the purpose of illustrating the techniques of the present disclosure, those skilled in the art will recognize that many more possible combinations and replacements are possible. The present disclosure is intended to cover all alternatives, variations, and modifications falling within the scope of this disclosure, including the claims.

1. A semiconductor device, comprising:
a substrate;
an element insulating layer, disposed on the substrate; and
a semiconductor resistive layer, disposed within the element insulating layer, wherein
the semiconductor resistive layer extends along a first direction perpendicular to a thickness direction of the substrate and includes an uneven portion along the thickness direction.

2. The semiconductor device of claim 1, wherein the uneven portion is multiply disposed and spaced apart from each other along the first direction.

3. The semiconductor device of claim 2, wherein the plurality of uneven portions are disposed in the same pitch along the first direction.

4. The semiconductor device of claim 1, wherein the uneven portion includes:
a first resistive portion, extending along the first direction;
a second resistive portion, located at a position shifted from the first resistive portion along the first direction and closer to the substrate than the first resistive portion, wherein the second resistive portion extends along the first direction; and
a connecting portion, extending along a direction intersecting the first direction and connecting an end of the first resistive portion along the first direction to an end of the second resistive portion along the first direction.

5. The semiconductor device of claim 4, wherein a length of the second resistive portion is less than a length of the first resistive portion.

6. The semiconductor device of claim 4, wherein a length of the connecting portion is greater than a thickness of the first resistive portion.

7. The semiconductor device of claim 4, wherein a length of the connecting portion is greater than a length of the second resistive portion.

8. The semiconductor device of claim 4, wherein
a direction perpendicular to both the first direction and the thickness direction is set as a second direction, and
the connecting portion extends obliquely with respect to the thickness direction when viewed from the second direction.

9. The semiconductor device of claim 1, further comprising a wiring layer electrically connected to the semiconductor resistive layer, wherein the wiring layer is disposed closer to the substrate than the semiconductor resistive layer along the thickness direction.

10. The semiconductor device of claim 1, further comprising a wiring layer electrically connected to the semiconductor resistive layer, wherein the wiring layer is disposed at a side opposite to the substrate with respect to the semiconductor resistive layer along the thickness direction.

11. The semiconductor device of claim 10, wherein the wiring layer is disposed on the element insulating layer and covered by a passivation film covering the element insulating layer.

12. The semiconductor device of claim 1, further comprising:
a wiring layer, electrically connected to the semiconductor resistive layer; and
a connecting wiring, connecting the semiconductor resistive layer to the wiring layer, wherein
the semiconductor resistive layer
is disposed at a position different from a position of the uneven portion along the first direction, and
includes a resistive end portion to which the connection wiring is connected.

13. The semiconductor device of claim 1, wherein
the semiconductor resistive layer is multiply disposed,
a direction perpendicular to both the first direction and the thickness direction is set as a second direction, and
the plurality of semiconductor resistive layers are spaced apart along the second direction.

14. The semiconductor device of claim 1, wherein the element insulating layer includes:
a substrate-side insulating layer, disposed on the substrate; and
a front-side insulating layer, laminated on the substrate-side insulating layer, wherein
the substrate-side insulating layer is formed by a plurality of first insulating films and a plurality of second insulating films alternately stacked with each other, the second insulating films are configured for relieving stress of the plurality of first insulating films, and
the semiconductor resistive layer is embedded in the surface-side insulating layer.

15. A semiconductor module, comprising:
the semiconductor device of claim 1;
a support member, supporting the semiconductor device; and
a sealing resin, sealing the semiconductor device and the support member.

16. A semiconductor module, comprising:
the semiconductor device of claim 2;
a support member, supporting the semiconductor device; and
a sealing resin, sealing the semiconductor device and the support member.
